(19) United States
(12) Patent Application Publication
(10) Pub. No.: US 2013/0323542 A1
(43) Pub. Date: Dec. 5, 2013

(54) Electrochemical Cell Based on Lithium Technology with Internal Reference Electrode, Process for Its Production and Methods for Simultaneous Monitoring of the Voltage or Impedance of the Anode and the Cathode Thereof

(71) Applicants: Charles Wijayawardhana, Wacken (DE); Gerold Neumann, Halstenbek (DE); Peter Gulde, Itzehoe (DE)

(72) Inventors: Charles Wijayawardhana, Wacken (DE); Gerold Neumann, Halstenbek (DE); Peter Gulde, Itzehoe (DE)

(21) Appl. No.: 13/879,293

(22) PCT Filed: Oct. 12, 2011
(86) PCT No.: PCT/EP11/67787

§ 371 Date: Aug. 22, 2013

(30) Foreign Application Priority Data
Oct. 13, 2010 (EP) 10187482.4

(51) Int. Cl. G01R 31/36; H01M 10/04; H01M 10/48

(52) U.S. Cl. CPC G01R 31/3606; H01M 10/48; H01M 10/04
USPC 429/50; 324/426; 324/430; 429/179; 29/623.5; 320/134

(57) ABSTRACT

The present invention is directed to an electrochemical cell based on lithium technology, comprising the following components: a positive electrode containing a cathode material, a separator made of an electrically insulating material, a negative a electrode containing an anode material, the electrodes and the separator having layer or sheet form, a liquid and/or solid ion conductor material for transportation of lithium ions between the positive and the negative electrode, the said components being sealed within a casing, wherein the positive and the negative electrode each comprise an electrically conducting structure extending through a wall of the casing for further electrical connection, characterized in that it further comprises: a reference electrode within the said casing which is electrically insulated from the positive and the negative electrode, the reference electrode having layer or sheet form comprising at least one non-metallic lithium compound, and an electrically conducting structure in layer or sheet form being in electrical contact with the said reference electrode, the electrically conducting structure extending through a wall of the casing for further electrical connection. The invention is further directed to a method for the preparation of this electrochemical cell, to a method for measuring the voltage or the impedance of a cathode and/or of an anode of such an electrochemical cell based on lithium technology, and to driving methods of said cell, decreasing aging phenomena and improving its life duration.

The present invention is directed to a lithium battery comprising layered components having an internal reference electrode incorporated therein, in order to alleviate simultaneous monitoring of the voltage and/or the impedance of the anode and the cathode, to provide the possibility that the battery is used at its maximum capacity and with enhanced safety.

A reference electrode is defined as an electrode that has a stable electrochemical potential which serves as a reference point for measuring the potential of one or more electrodes in an electrochemical cell.

In the past, reference electrodes have mainly been used externally. Table 1 below summarizes the key properties of the most important reference electrodes of the prior art and their compatibility with lithium-ion/polymer cells:

| | | Chemical | | Overall |
|---|---|---|---|---|
| | | compatibility | Manufacturable | compatibility |
| | | to Li- | compatibility to | to Li- |
| Reference | Reference redox | ion/polymer | Li-ion/polymer | ion/olymer |
| electrode | reactions | cells | cells | cells |
| Silver-silver | AgCl + e⁻ [symbol] Ag + Cl⁻ | Poor | Incompatible | Incompatible |
| chloride | (0.222 V vs. NHE at | | | |
| (Ag/AgCl) | 25° C.) | | | |
| Calomel | Hg₂Cl₂ + 2e⁻ [symbol] 2Hg + | Poor | Incompatible | Incompatible |
| reference | 2Cl⁻ | | | |
| electrode | (0.222 V vs. NHE at | | | |
| (SCE) | 25° C.) | | | |
| Normal hydrogen | 2H⁺(aq) + 2e⁻ → H₂(g) | Incompatible | Incompatible | Incompatible |
| electrode | | | | |
| (NHE) | | | | |
| Pure metal | Examples: | Some | Incompatible (see | Incompatible |
| and metal | 1) Li⁺ + e⁻ → Li | compatible | text below) | |
| alloy wires | 2) Ag⁺ + e⁻ → Ag | (e.g. Li metal) | | |
| | 3) Pt & Pt-oxide | | | |
| | systems | | | |

Of the above, the Ag/AgCl, NHE, and SCE reference electrodes are generally used in electrochemical systems consisting of aqueous electrolytes. Therefore, they are not suitable for direct use in lithium polymer cells which are based on organic solvents. It should be noted, however, that these electrodes can be adapted for use in organic solutions with the use of a double salt bridge (which minimizes mixing of solvents) (U.S. Pat. No. 3,103,480, U.S. Pat. No. 4,282,081, U.S. Pat. No. 4,401,548). In the case of lithium batteries, such electrodes pose special problems. One is that these electrodes are not fully impermeable to mixing, so the inevitable rise in water content in the battery will greatly decrease the performance of the battery. It is well known that water content in a battery must be kept as low as possible (i.e., in the 100 ppm range). Second, there is no foreseeable way in which such a double salt bridge electrode could be physically incorporated in a lithium polymer cell. As noted in Table 1, pure metal or metal alloy wires, too, can be used as reference electrodes. There have been a few journal publications and at least one commercial source where such systems have been reported [(D. W. Dees, A. N. Jansen, D. P. Abrahams, J. Power Sources 174 (2007) 1001) & (www.el-cell.com)] In all these systems, the reference electrode is simply a wire consisting of Li, a lithium alloy such as Li_{y}Sn, or a SnCu wire, lithiated in situ, which is inserted from the side to make contact with the separator. All such systems, which require extensive manual manipulations, are meant for laboratory use and are incompatible with commercial lithium-ion/polymer cell technologies.

A wire-type reference electrode is also shown in WO 2009/036444 A2. Alternatives disclosed in this document are a reference electrode having the shape of a pin, or use of the metallic casing as the reference electrode.

Inbuilt reference electrodes made of Li—Sn alloy in laboratory scale half-cells have shown that it is possible to measure the impedance over the anode-reference and cathode-reference loops independently, thus allowing, for example, the monitoring of the relative contributions of the anode and cathode towards the overall impedance of the battery [see D. P. Abraham, R. E. Reynolds, E. Sammann, A. N. Jansen, D. W. Dees, Electrochim. Acta 51 (2005) 502)]. The electrode was prepared in this case from a 25 μm diameter tin-coated copper wire which had been lithiated in situ, producing a Li_{˜4,4}Sn alloy which is described to display a relatively stable voltage at room temperature [D. P. Abraham, S. D. Poppen, A. N. Jansen, J. Liu, D. W. Dees, Electrochim. Acta 49 (2004) 4763-4775)].

Two different variants of the above wire type reference electrode were tested upon manual incorporation into a small, lab-scale cell developed at Argonne National Lab: one sandwiched between the anode and cathode; the other placed slightly outside the separator where there is free electrolyte. Both configurations succeeded in measuring the impedance at the anode and cathode separately [see D. W. Dees, A. N. Jansen, D. P. Abrahams, J. Power Sources 174(2007)1001]. Furthermore, the two types yielded very similar results; thus favoring the external reference, which is often simpler to incorporate in a cell.

Although these cells have shown the value of determining the impedances at the anode and the cathode independently, the wire type reference electrode, which needs to be manually inserted, is not a practical solution for integrating a reference electrode into commercial lithium ion/polymer cells. The reasons for this stem from the physical nature of the wire electrode. It needs to be incorporated after the main components have been already assembled; it is difficult to place it correctly; the tiny wires tend to break or deform; and there is the danger that another structure of the cell, for example the separator, or the pouch or other casing, is penetrated, causing immediate cell failure or opening the door for the gradual cell degradation through processes such as the formation of dendrites which decrease cell capacity, and worse, might cause a short circuit. The same disadvantages result in using a pin as the reference electrode.

Another approach is shown in JP 2007-193986, namely use of a lithium foil, having a thickness of about 15 times that of the anode and the cathode active layer, and about 20 times that of the separator as a reference electrode, which is connected to a copper wire. The reference electrode may be placed at a distance to the positive electrode of about 1 mm. This approach is likewise not suitable for the integration of a reference electrode into a lithium foil battery by lamination of the components, because it would call for different fabrication processes.

The known, commercially available lithium-ion/polymer batteries usually consist of a 2-electrode configuration (anode and cathode). Independent determination of their key battery parameters including the voltage and the impedance over the cathode and the anode loops via a fully integrated reference electrode is not possible until now. Knowledge of the voltages of the anode and cathode should, however, increase the safety of the battery by providing information on when the anode and/or the cathode reaches unsafe voltages, which could, for example, lead to thermal runaway. Yet it is a fact that it is often necessary to drive the voltage of the anode and/or cathode very close to the safety limits, in order to obtain the maximum capacity out of a battery. However, in the absence of a reliable method to determine the individual voltages at the anode and cathode, some trade-offs between safety and capacity yield must be made.

It is the problem of the present invention to provide a means and methods which overcomes the disadvantages of the prior art and which enables determination of the voltage and the impedance over the cathode and the anode loops independently, without additional preparation steps during the fabrication of the batteries which have to be performed separately and outside the standard fabrication.

This problem is solved by providing an electrochemical cell based on lithium technology comprising the following components:
a positive electrode containing a cathode material,
a separator made of an electrically insulating material,
a negative electrode containing an anode material, the electrodes and the separator having layer or sheet form,
a liquid and/or solid ion conductor material for transportation of lithium ions between the positive and the negative electrode,
the said components being sealed within a casing (usually flat or wound up to a roll), wherein the positive and the negative electrode each comprise an electrically conducting structure extending through a wall of the casing for further electrical connection, characterized in that it further comprises:
a reference electrode within the said casing which is electrically insulated from the positive and the negative electrode, the reference electrode having layer or sheet form comprising at least one non-metallic lithium compound, and an electrically conducting structure in layer or sheet form being in electrical contact with the said reference electrode, the electrically conducting structure extending through a wall of the casing for further electrical connection.

The term “based on lithium technology” shall be understood to include any kind of cell wherein the transport of the charges between the cathode and the anode balancing the intake or output of electrical current is provided via transport of lithium ions. The electrochemical cell can be a lithium battery, e.g. a primary type battery, but will in most cases be a lithium accumulator, i.e. a secondary type battery, comprising a positive electrode containing a cathode material, a separator made of an electrically insulating material, a negative electrode containing an anode material, and a liquid and/or solid ion conductor material for transportation of lithium ions between the positive and the negative electrode. This means that not only the “conventional” lithium batteries, accumulators and the like are comprised by the present invention, but also other closely related electrochemical cells which function on the principle of lithium ion transport. This is e.g. the case for systems which include rechargeable lithium-sulfur (Si—S) and Li-Air cells. These and comparable systems are regarded as systems “based on lithium technology” as described above, as well.

In many cases, the electrical conducting structure extending through a wall of the casing for further electrical connection will be a piece of metal or expanded metal, respectively, but alternatively, it can e.g. be made from a respective electrode material, in case this material is selected such that leakage of liquid electrolyte is avoided (e.g. it is free of pores) or in case no liquid electrolyte is used within the cell. It usually has the form of a tab.

The cathode material is usually laminated to a cathode current collector, and likewise, the anode material is usually laminated to an anode current collector. These collectors often consist of a metal sheet or an expanded metal sheet. In these cases, the electrical conducting structure of the anode and of the cathode, extending through a wall of the casing, can be a piece of metal or expanded metal, preferably in sheet form, laminated to the respective current collector, or can be an integral part of the said current collector. The reference electrode may be provided in a comparable form, i.e. laminated or otherwise applied (e.g. coated) onto a current collector of an optionally expanded metal sheet which may be in direct electrical contact with the electrical conducting structure extending through a wall of the casing and possibly being integrally connected thereto (see also the below details).

Although not always necessary (e.g. if the electrode material has inherent binding properties as it may be the case for nanoparticulate materials), the cathode material and the anode material will usually be present in admixture with a binder which allows its provision in layer form, for example in sheet form, as known in the art. As a binder, usually an organic polymer is used, for example a fluorinated alkene. Polyvinylidene and its copolymers have been proven as specifically useful for the preparation of such electrodes. Likewise, the reference electrode material can be in admixture with such a binder. As well, the separator may have layer or sheet form, and may be electrochemically inert, or may include a solid polyelectrolyte material, such as Li_{1,3}Al_{0,3}Ti_{1,7}(PO₄)₃, LiTaO₃.SrTiO₃, LiTi₂(PO₄)₃.LiO₂, LiH₂(PO₄)₃.Li₂O, Li₄SiO₄.Li₃PO₄, Li₉AlSiO₈, LiAlSi₂O₆ (Spodumene), LiX+ROH, wherein X is Cl, Br, I (1, 2 or 4 ROH per LiX), or the like. Separators are known in solid and in gel form. Lithium ion transport may function, in some cases, via the solid/gelified electrolyte material within the separator only; in most cases, it will be supported or completely provided by the presence of a liquid electrolyte material, for example a lithium salt like lithium hexaflurophosphate or the like in a suitable solvent, for example in a plasticizer having formula A¹-D-A² wherein A¹ and A² are independently selected from R¹, OR¹ SR¹ or NHR¹ wherein R¹ means e.g. C₁-C₆ alkyl or R¹ and R² form together with D a hetero ring having five ring members, and wherein D can be C═O, S═O. C═NH or C═CH₂ or, in case it forms a hetero ring with R¹ and R², can additionally be selected from O, S, NH and CH₂. Oftenly used examples are ethylene carbonate, propylene carbonate, dimethyl carbonate, γ-butyrolactone, dioxolane, or dimethylsulfoxide.

The thickness of the cathode layer and the anode layer as well as that of the reference electrode layer can freely be selected; usually, it is in the range of about 80 μm to 500 μm, more preferable of about 110 μm to 350 μm and most preferable of about 120 to 250 μm. However, for specific cases, e.g. for electrochemical cells intended for long lasting use (e.g. 15 to 20 years), it may be favorable to use layers of from more than 500 μm, e.g. 600 μm up to 1 mm or even more, in order to overcome the adversarial effect if a current will inadvertently be drawn through the reference electrode during voltage measurement. Although this current is of a very tiny amount (in the range of pico Amperes), it will often inevitably occur.

The current collector sheet can have a thickness of about 5 to 300 μm, preferably of about 100 to 200 μm, although thicknesses outside the mentioned ranges are possible.

The cell may be a single cell, including one electrode, one separator and one anode, or a bicell or multicell stack comprising more than one cathode and/or more than anode, for example arranged such that a first, flat current collector is in contact with respective electrodes on both of its flat sides, which each are in ion-conducting contact with a respective counter electrode. The said counter electrodes are laminated to their respective current collectors as well. If desired, these current collectors may again be in contact with a second electrode material which could be in ion-conducting contact with a further counter-electrode, and so on. The single cell or bi or multicell stack is usually packaged within a foil, pouch or other casing made of an insulating material, usually an organic polymer, in order to avoid leakage and contact with external moisture and other contaminants. Use of a laminated material for the pouch or other casing is possible; this material may include a metallic foil, if required or desired; however, a laminated of merely organic layers are preferred. Tabs or other contacts connected to the current collectors extend through a wall of the foil or other casing for further electrical connections.

Independent of whether the electrochemical cell based on lithium technology of the present invention is a single cell or a bi or multicell stack, it may contain one or, alternatively, two or more reference electrodes. If the cell comprises current collectors, one of the said reference electrodes can be placed on the or one cathode current collector and one other thereof can be placed on the or one anode current collector.

The description of the invention is accompanied by figures, wherein

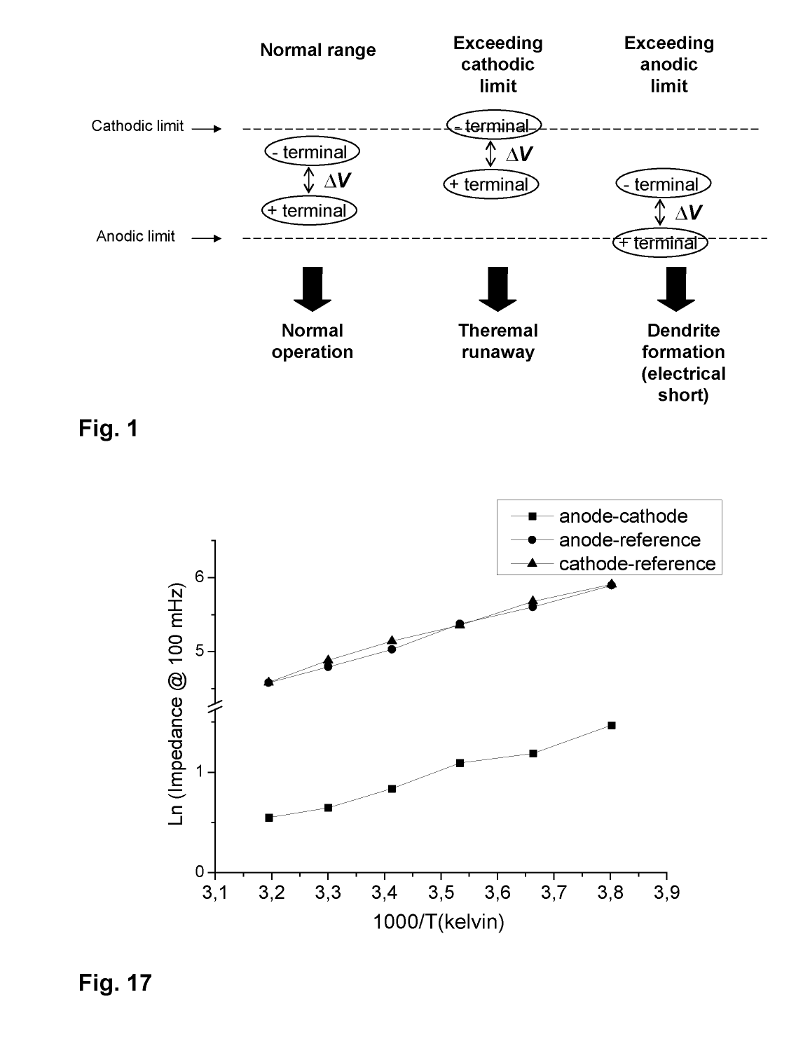

FIG. 1 is a scheme highlighting possible voltage overshoots with potential safety hazards,

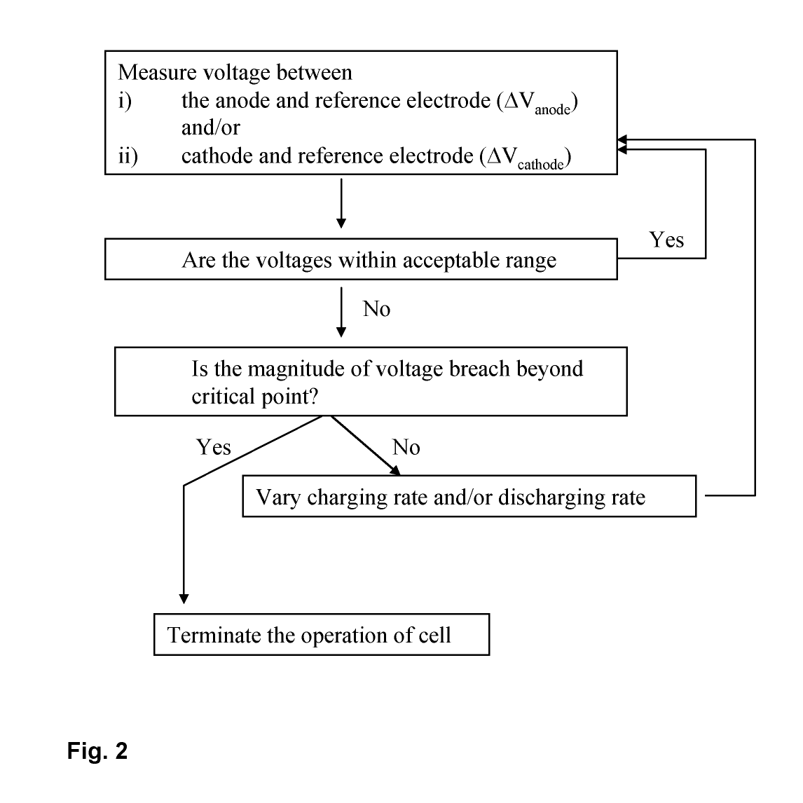

FIG. 2 outlines the battery management system involving the voltage measurements,

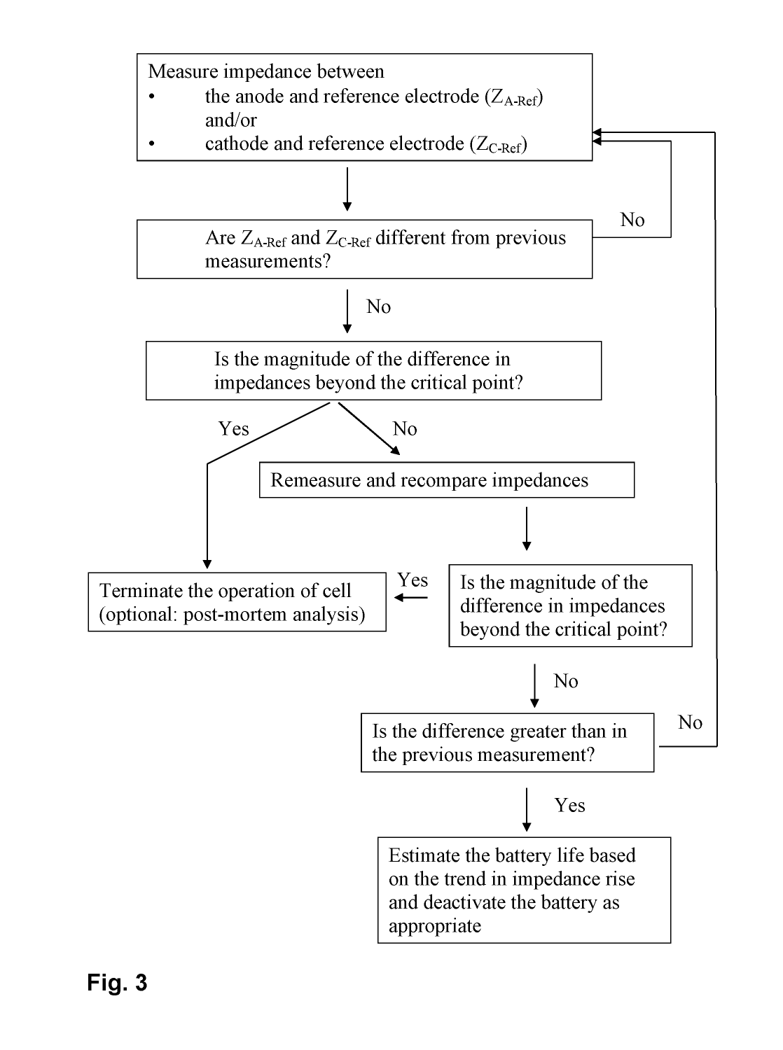

FIG. 3 outlines the battery management system surrounding,

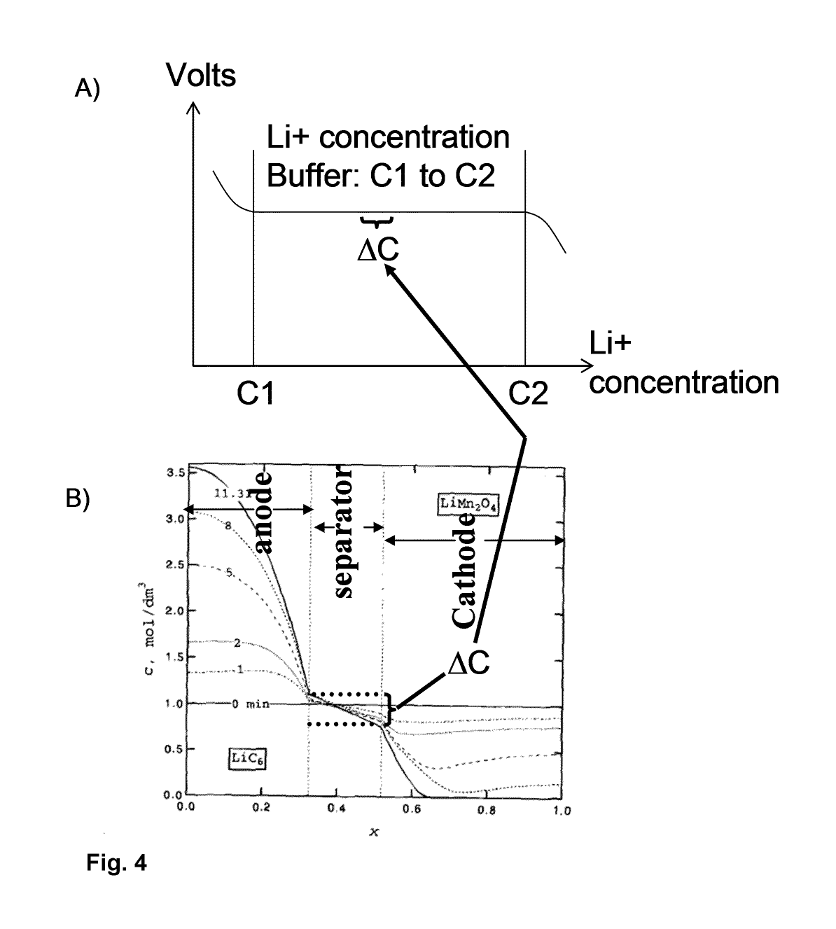

FIG. 4 indicates A) the hypothetical voltage versus salt concentration profile of the desired reference electrode and B) salt concentration profiles across the anode, separator, and cathode of a representative li-ion cell during discharge. Time since beginning discharge is given in minutes (0-11.31 minutes) [B) adapted from J. Electrochem. Soc. 143 (1996) 1890],

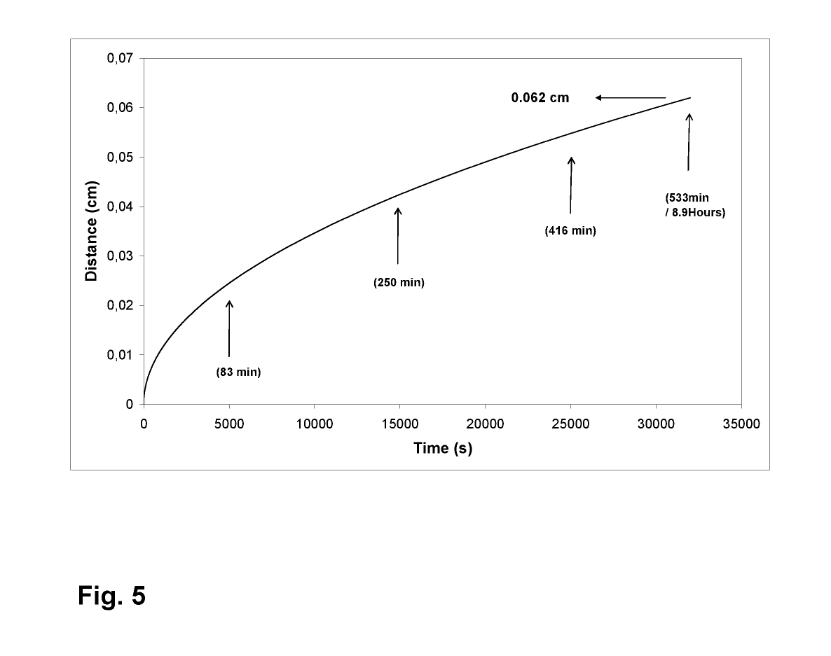

FIG. 5 indicates the diffusion layer thickness (distance) versus time plot for EC/DMC where D₀=3.00×10⁻⁸ cm²/s.,

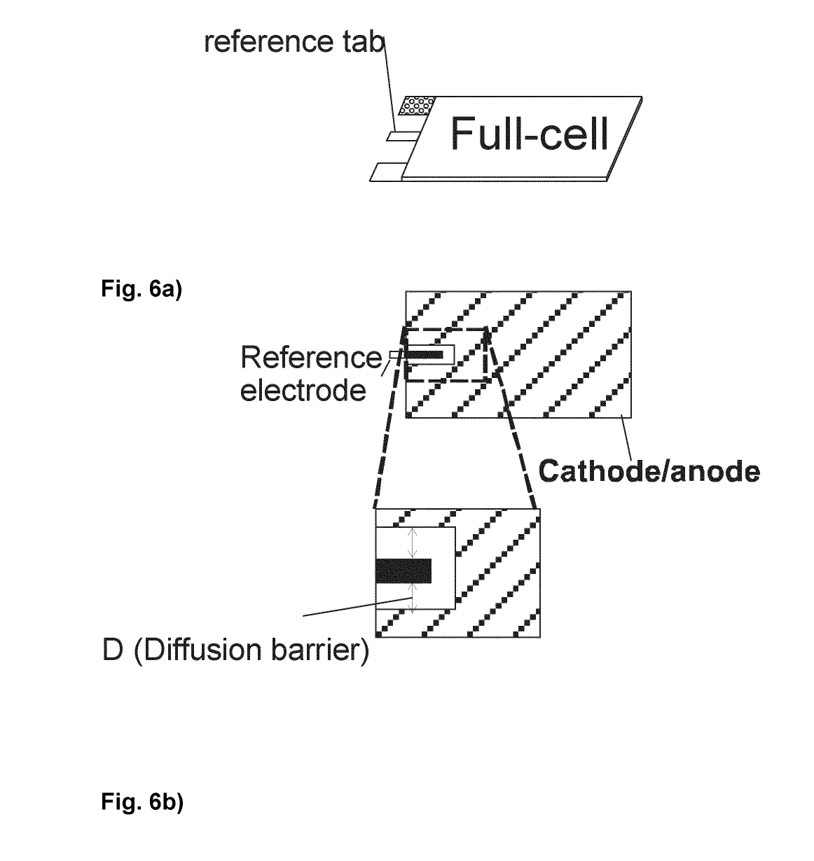

FIG. 6 indicates A) the top-side view of a full cell, B) the magnified view showing the diffusion gap,

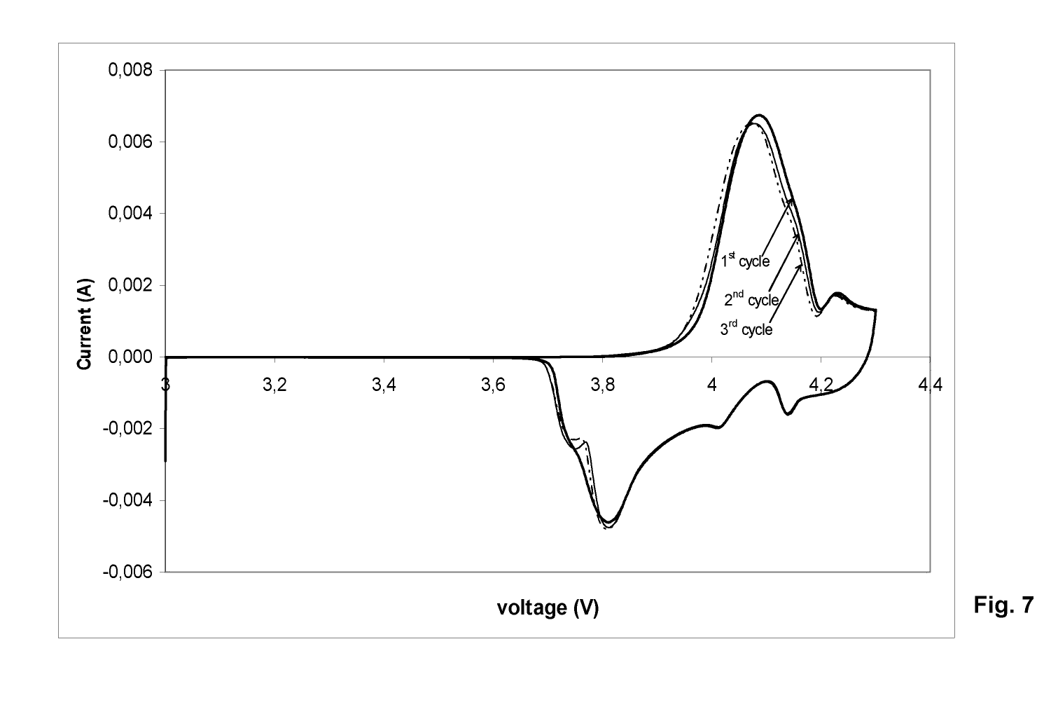

FIG. 7 shows the first 3 cyclic voltammograms of a LiCoO₂ cathode under experimental conditions of scan-rate100 μV/s and voltage versus Li/Li⁺ reference,

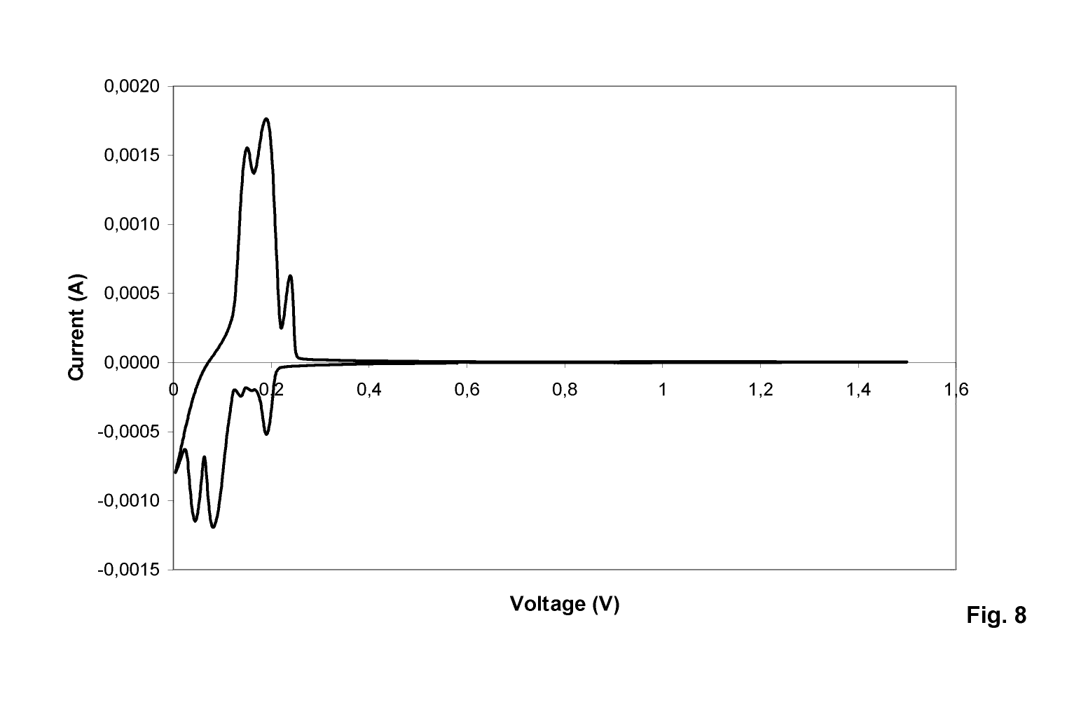

FIG. 8 depicts the linear sweep voltammogram of graphite anode under experimental conditions of scan-rate10 μV/s and voltage versus Li/Li⁺ reference,

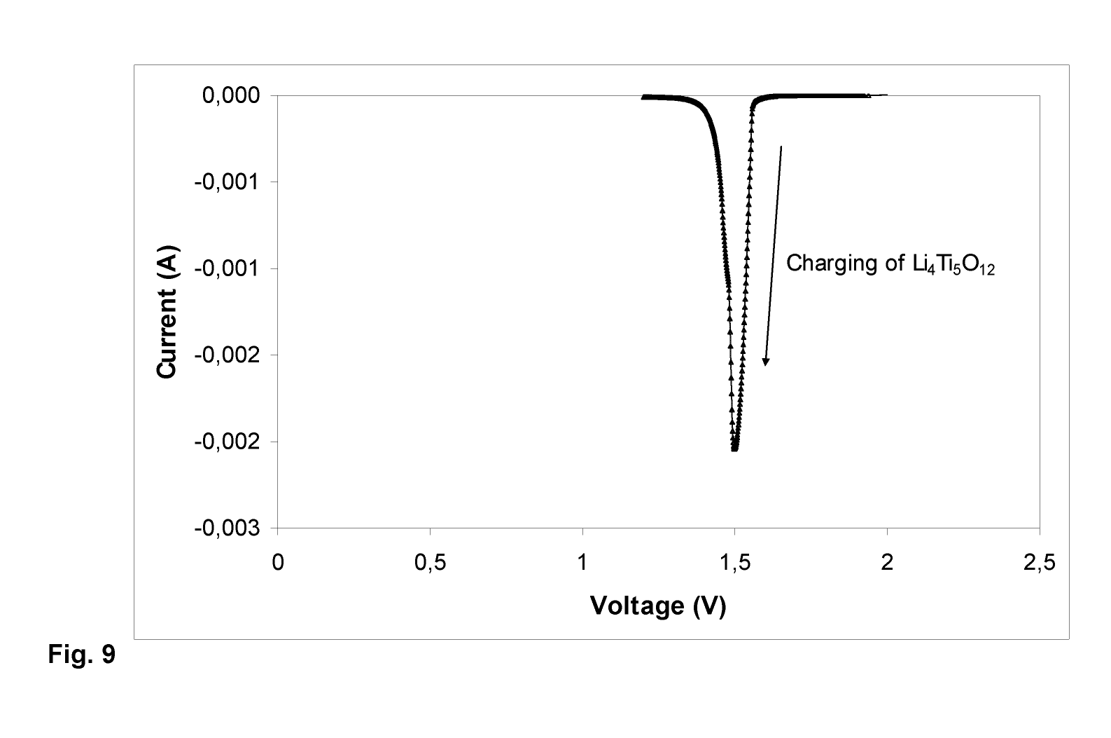

FIG. 9 depicts the linear sweep voltammogram of Li₄Ti₅O₁₂ reference electrode under experimental conditions of scan-rate10 μV/s and voltage versus Li/Li⁺ reference,

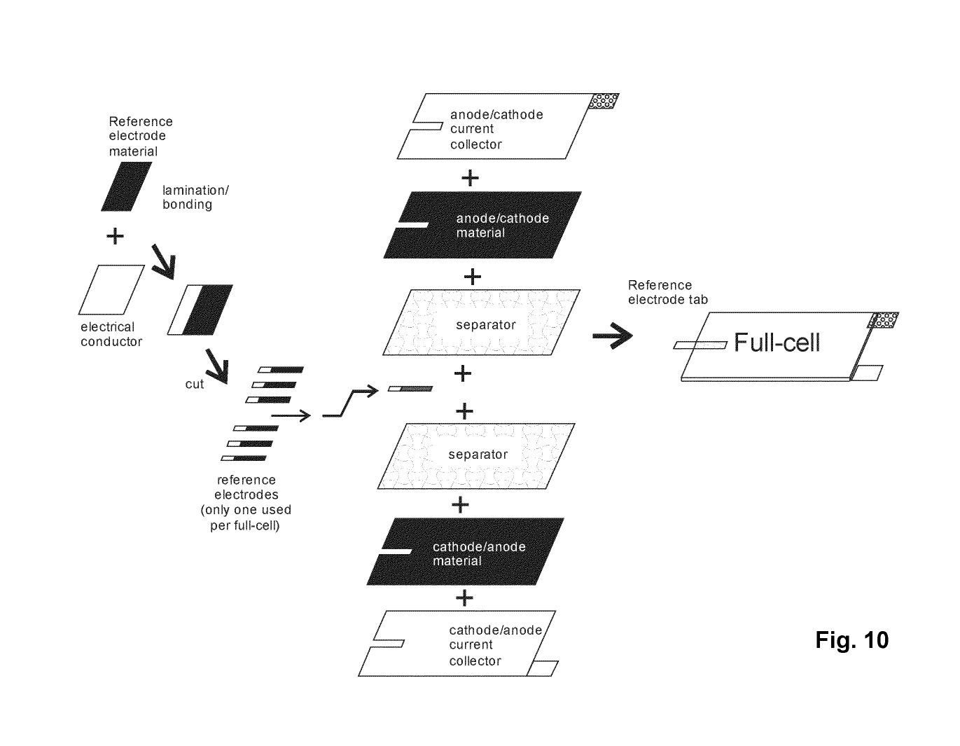

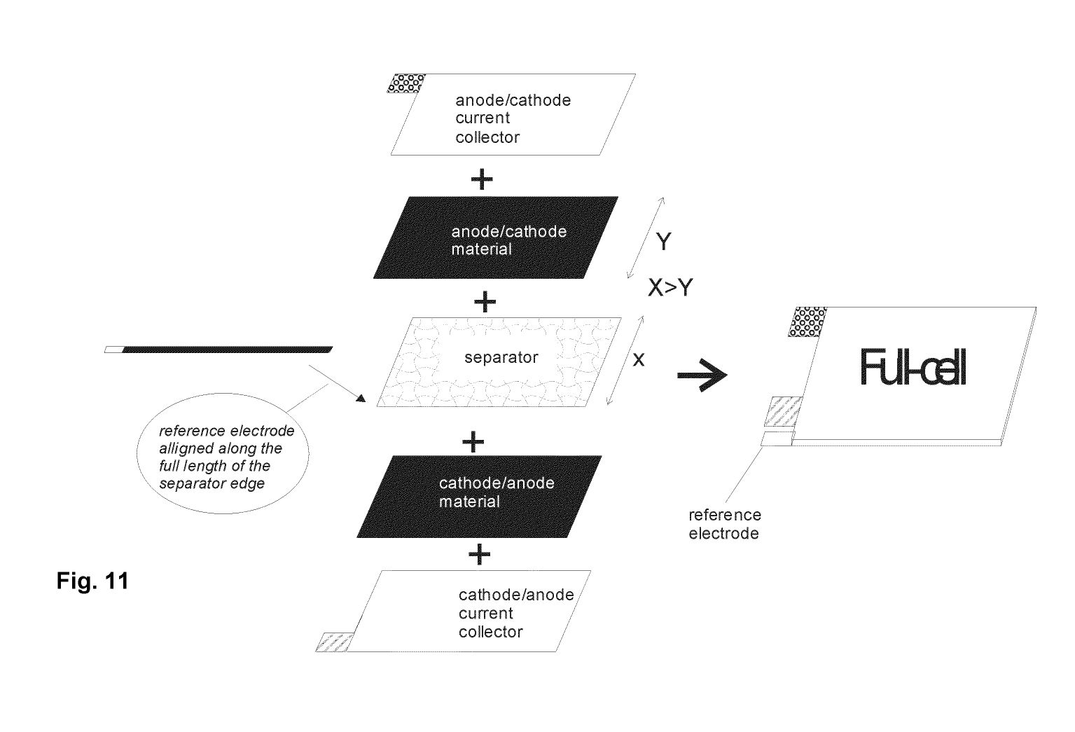

FIGS. 10 to 13 show specific designs of the inventive electrochemical cell construction,

FIG. 14 is a comparison of the charge-discharge behavior of the different cells (A) standard lithium cell (B) embodiment as shown in FIG. 10, (C) embodiment as shown in FIG. 11 (see text for details),

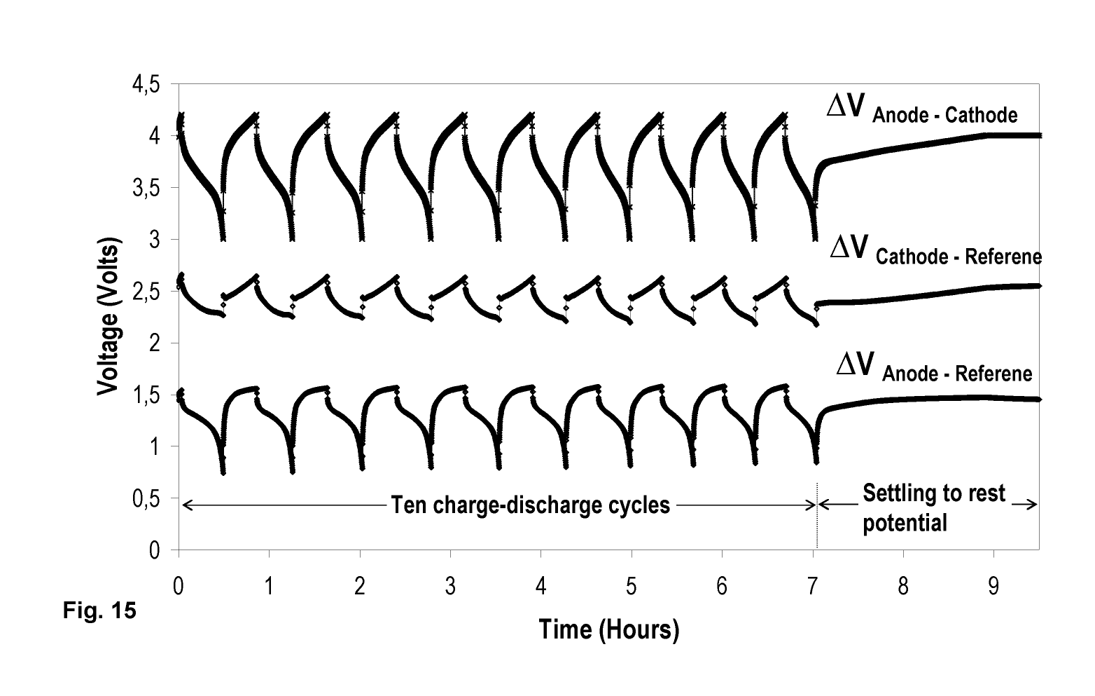

FIG. 15 indicates the simultaneous measurement of voltage between a) anode-cathode, b) cathode-reference, and c) anode-reference over the charge-discharge profile of 10 cycles with 10 between 3.0V and 4.2V followed by settling rest potential of 4.0 V. The anode, cathode, and reference electrode of this example contained graphite, LiCoO₂, and lithium titanate oxide, respectively,

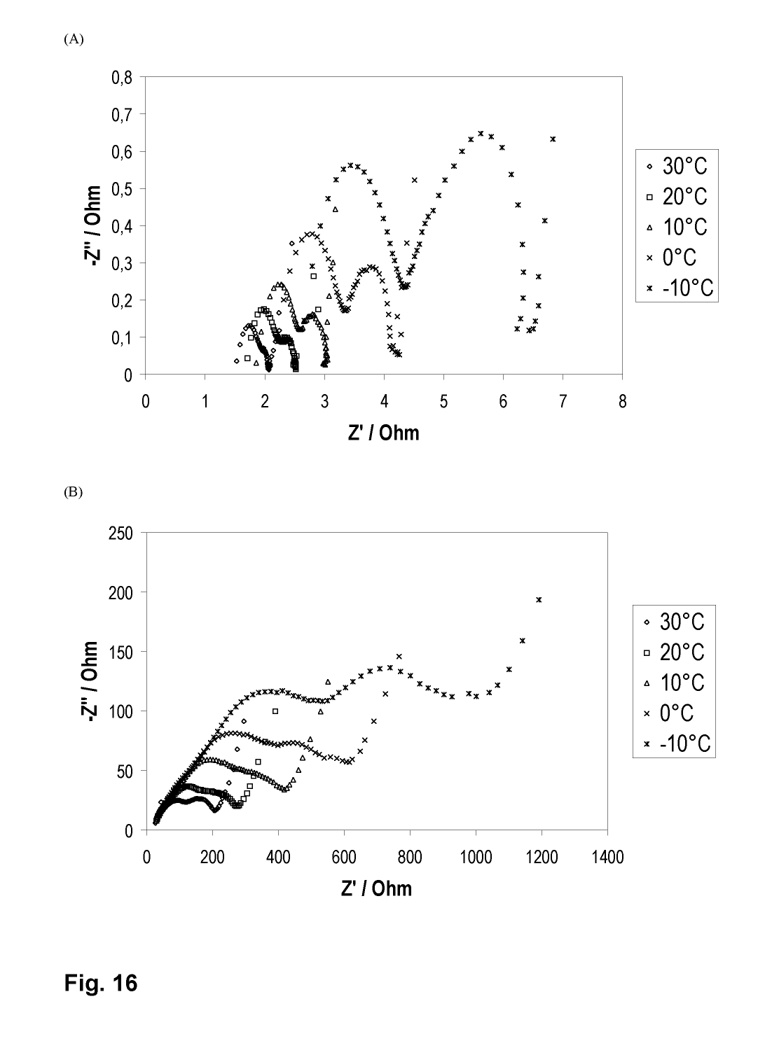

FIG. 16 is a diagram indicating impedance versus temperature measurement on an inventive three electrode cell with impedance spectra plotted as Nyquist plots for (A) anode—cathode loop and (B) anode—reference electrode. The anode, cathode, and reference electrode of this example contained graphite, LiCoO₂, and lithium titanate oxide, respectively,

FIG. 17 is a diagram indicating an Arrhenius plot of Ln (Impedance) versus 1/temperature for the impedance measured at 100 mHz over the loops of a) anode-cathode, b) anode-reference and c) cathode-reference. The anode, cathode, and reference electrode of this example contained graphite, LiCoO₂, and lithium titanate oxide, respectively,

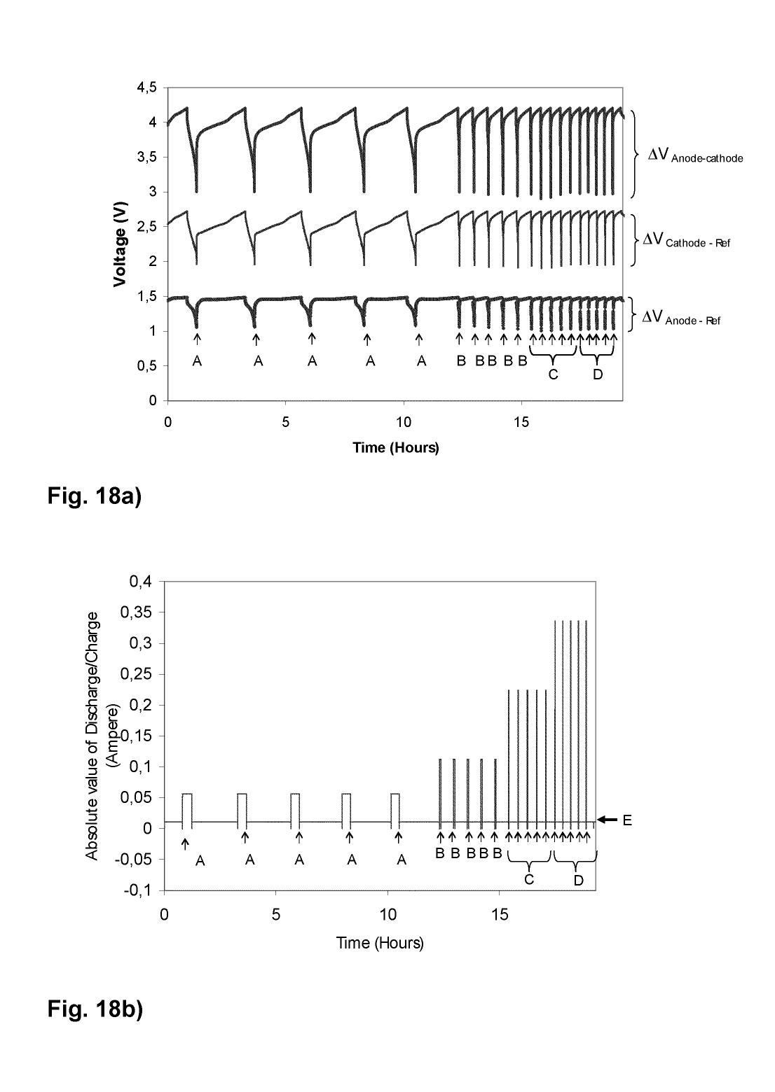

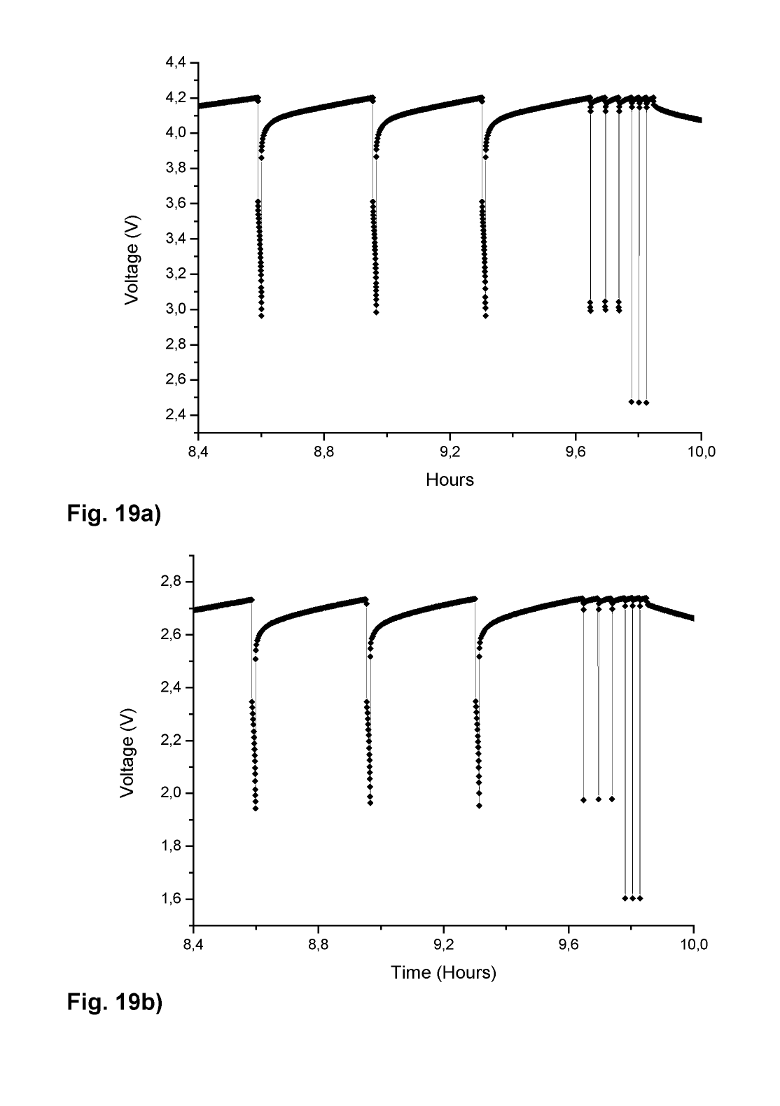

FIG. 18 is a diagram of simultaneous measurement of voltage between a) anode-cathode, b) cathode-reference, and c) anode-reference over 0.2 C charging and 1 C, 2 C, 4 C, 6 C discharge, The anode, cathode, and reference electrode contained graphite, LiCoO₂, and lithium titanate oxide, respectively.

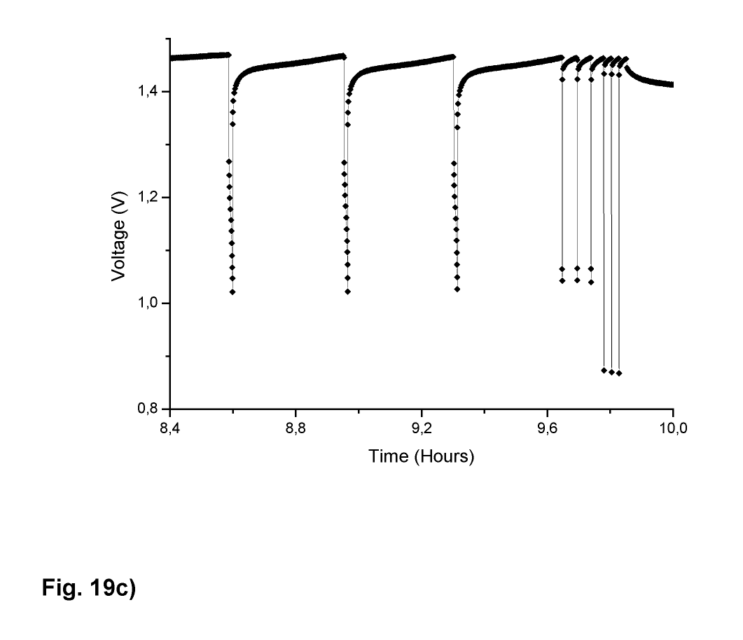

FIG. 19 is a diagram of simultaneous measurement of voltage between a) anode-cathode, b) cathode-reference, and c) anode-reference over 0.2 C charging and 8 C, 16 C, 32 C discharging with 3 discharges per each C-rate. The anode, cathode, and reference electrode of this example contained graphite, LiCoO₂, and lithium titanate oxide, respectively,

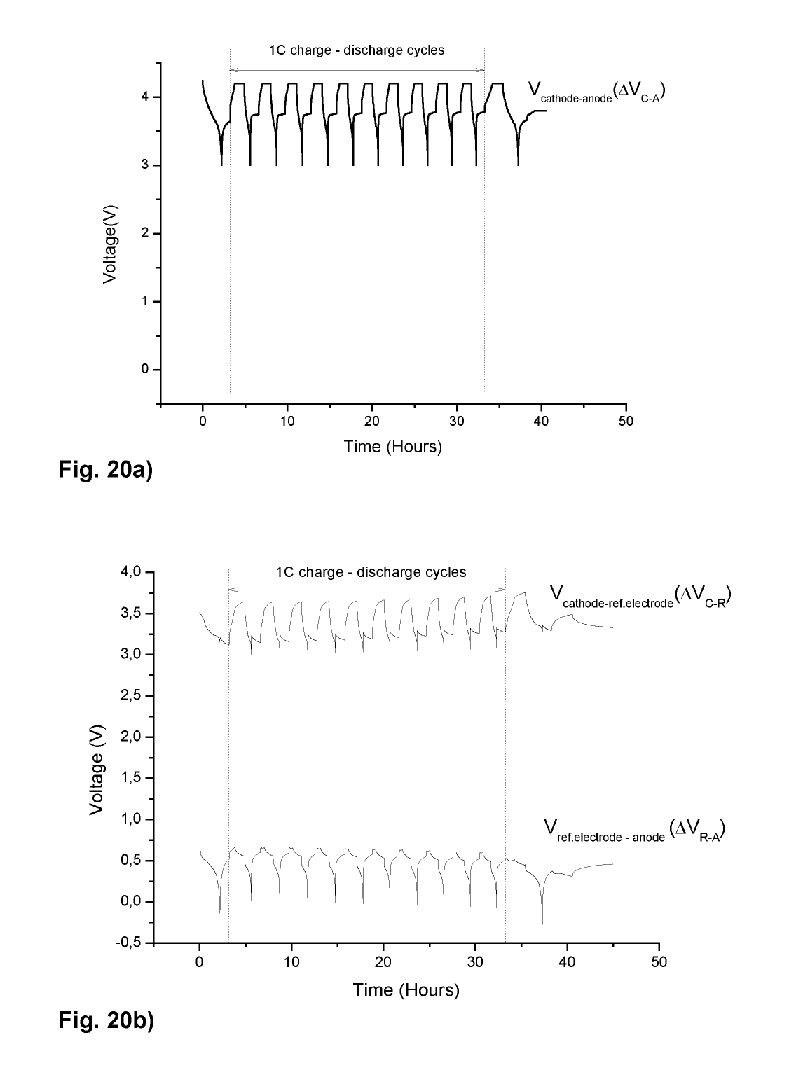

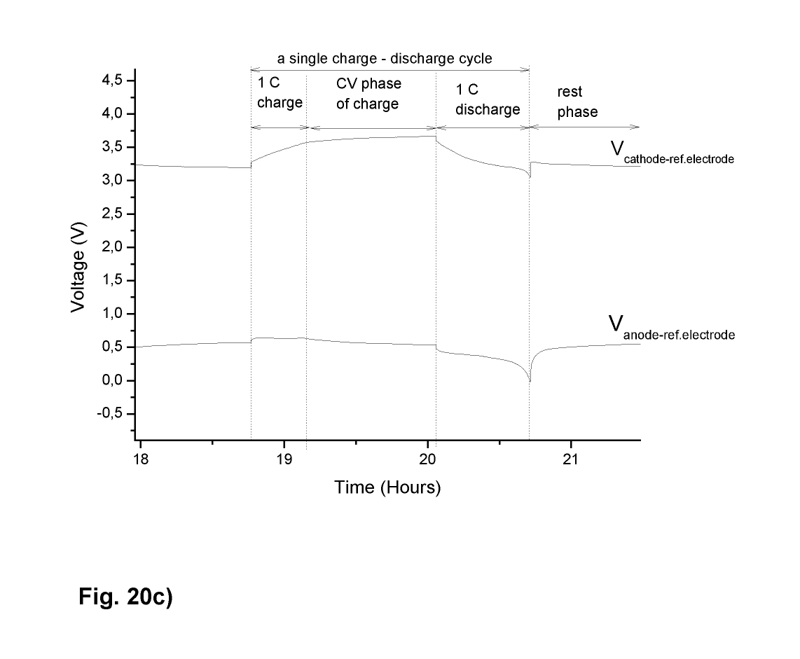

FIG. 20 depicts a full cell voltage measurement during charge and discharge cycles (FIG. 20a) which is simultaneously tracked with the anode and cathode voltages against a LFP reference electrode (FIG. 20b) which allows clear discrimination of the different voltage contributions of the anode and cathode (FIG. 20c). The anode and cathode consist of graphite and LiCoO₂, respectively. (See examples for further details),

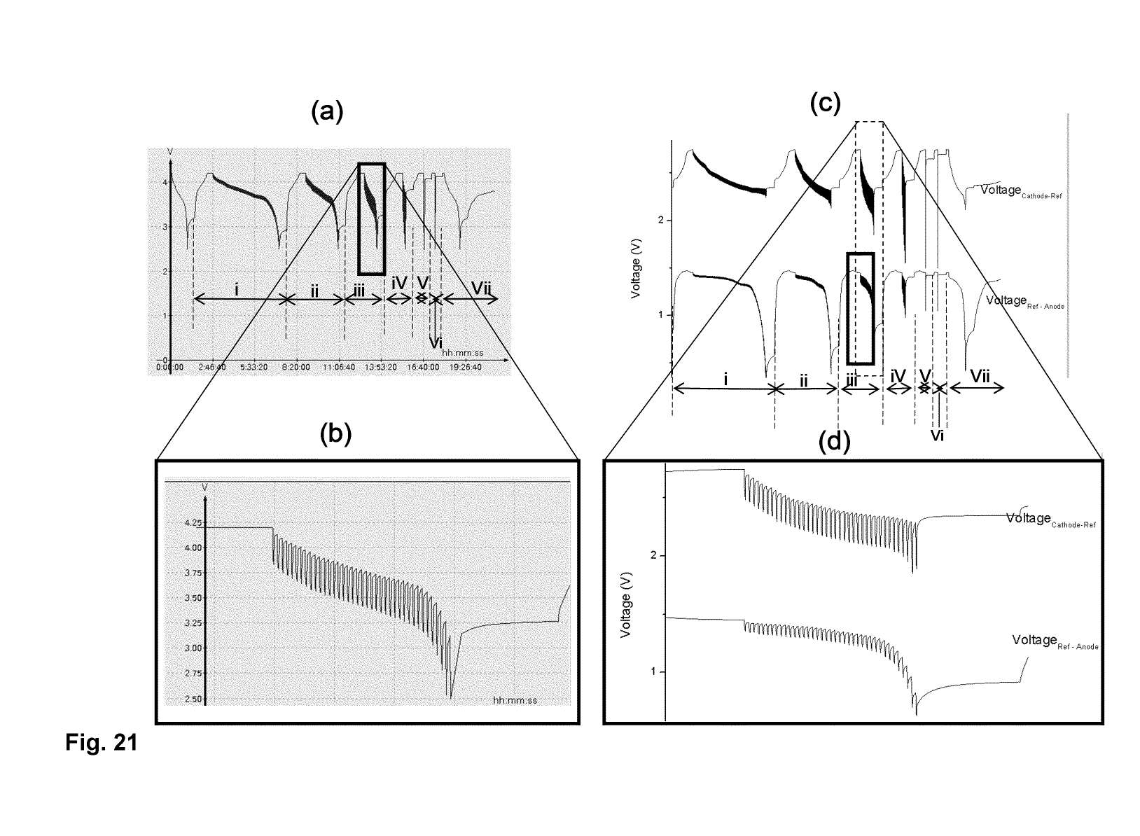

FIG. 21 depicts charge and discharge cycles with pulse discharges with (a) and (b) showing the voltage between the anode and cathode (ΔV_{C-A}) and FIG. 21(c) and (d) showing the voltages at the anode (ΔV_{R-A}) and cathode (ΔV_{C-R}) as measured against the reference electrode. All charging events were done at 0.2 C CC-CV and the discharges over the range of 1-30 C where i) is 1 C, ii) 2 C, iii) 5 C, iV) 10 C, v) 20 C and vi) 30 C. Each pulse was 18 seconds long and was followed by a 60 second open-circuit rest period before the next pulse. The anode, cathode, and the reference electrodes consist of graphite, LiCoO₂, and LTO, respectively. (See examples for further details),

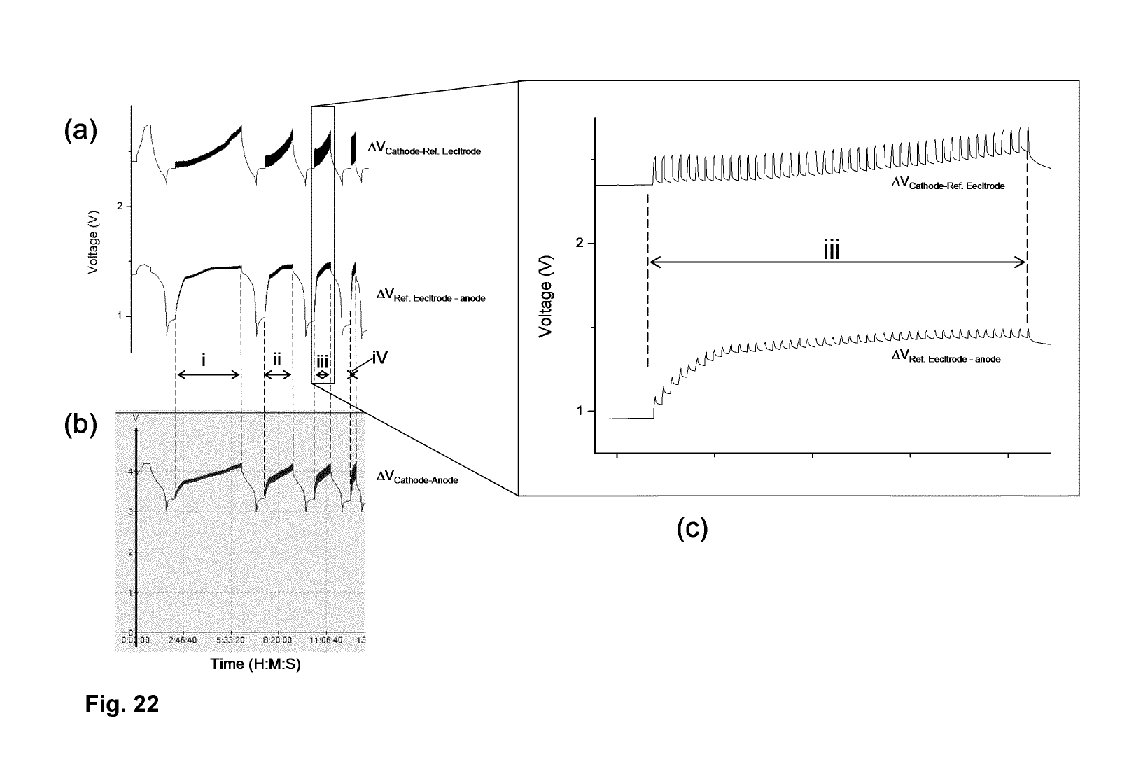

FIG. 22 depicts charge and discharge cycles with pulse charges of i) 1 C, ii) 2 C, iii) 3 C, and iv) 5 C with each pulse being 18 seconds long followed by a 60 second open-circuit rest period before the next pulse. The anode, cathode, and the reference electrodes consist of graphite, LiCoO₂, and LTO, respectively (see examples for further details).

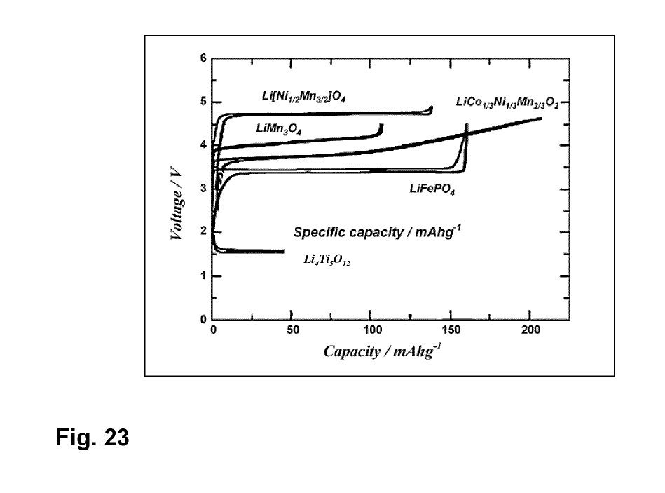

FIG. 23 indicates the voltage versus capacity of lithium ion (salt) intake profiles for several chemical electrode materials useful in the present invention.

In order to overcome the drawbacks of the prior art, the inventors of the present invention came to the conclusion that a reliable internal reference electrode for measurement of voltage and impedance within a closed cell should have the following properties:
A voltage drift as minimal as possible
Chemical compatibility with lithium technology
Robust electrode system without aging effects.

The electrochemical cell of the present invention is characterized in that it comprises a reference electrode comprising or made of at least one non-metallic lithium compound. In all embodiments of the invention, this compound is preferably selected under Li₄Ti₅O₁₂, LiFePO₄, Li(Ni_{0.5}Mn_{1.5})O₄. LiCoO₂, LiMn₂O₄, LiNiO₂, LiNi_{0.8}Co_{0.15}Al_{0.05}O₂(NCA), LiCo_{1/3}Ni_{1/3}Mn_{1/3}O₂ (NMC), Li₂FePO₄F, Li(LiₐNiₓMn_{y}Co_{z})O₂, Graphite (LiC₆), disordered carbon (hard and soft carbons), Si(Li_{4.4}Si), and Ge(Li_{4.4}Ge). Those compounds in which lithium is present in zerovalent (not positively charged) condition can be introduced into the cell in a precursor state without lithium. As soon as the cell is cycled for the first time, lithium atoms will be incorporated therein, resulting in the lithium containing compound.

Under the materials mentioned above, Li₄Ti₅O₁₂, LiFePO₄, and Li(Ni_{0.5}Mn_{1.5})O₄, are more preferred, and Li₄Ti₅O₁₂ and LiFePO₄ are most preferred.

This finding is based on the following considerations: The above mentioned compounds meet the requirements of compatibility with lithium technology in batteries and accumulators. In contrast to metal or alloy materials, they are usually present in the form of a powder, which can be combined or incorporated into an organic polymer, thus opening the possibility to use the same production methodology and the same consistency or chemical composition of the organic components present in the cathode, the anode, and the reference electrode. Ideal candidates for the reference electrode will be those known for their exceptional stability in lithium ion/polymer cells (e.g., LiFePO₄, Li₄Ti₅O₁₂), and therefore, they are specifically preferred. However, considering that a reference electrode acts as a potentiometric sensor (i.e., remains under equilibrium conditions), which by definition passes no significant current, the aging phenomena associated with active anode or cathode materials (e.g., aging due to continuous cycles of expansion and contraction) are absent at the reference electrode. Therefore, the choice of materials may be extended to all other materials compatible with lithium ion technology and mainly to those mentioned above.

The voltage drift of a reference electrode arises from instabilities in the redox reaction governing the reference electrode chemistry. As an example, in the classic Ag/AgCl reference electrode (AgCl+2e⁻ [symbol] Ag+Cl⁻), the potential (E) is determined by the Nernst equation:

$$E = {E}^{{0}^{′}} + \frac{RT}{nF} ln \frac{1}{[ {Cl}^{-} ]}$$

where,

E^{0′}=formal potential; R=molar gas constant; F=Faraday constant;

n=number electrons involved in redox reaction; T=temperature;

[Cl⁻]=concentration of Cl—

Over time, the loss of Cl⁻ or from a standard Ag/AgCl reference electrode and the accompanying decrease in chloride ion concentration causes a voltage drift. Similarly, any drift in temperature would also lead to a voltage shift.

In a first embodiment of the invention, such a voltage drift is prevented by using an electrode with a flat voltage versus lithium-ion concentration profile.

In this type of the reference electrodes described here, the reference electrode chemistry is chosen such that it is sensitive to Li⁺ but holds a nearly constant voltage over the entire range of Li⁺ concentrations the electrode encounters (FIG. 4). Such a reference electrode may be placed anywhere in the separator, as far as it is electrically insulated against the other electrodes. Furthermore, such an electrode can be miniaturized as its function is governed by potentiometric principles (i.e., negligible current flow). The relatively minor changes in the Li⁺ concentration within the separator, which is in sharp contrast to that within the electrodes, also prevents any significant build-up or depletion of Li⁺ in the separator (J. Electrochem. Soc. 143 (1996) 1890). Several candidate electrochemical systems meet the above criterion (see FIG. 23). In particular, the systems especially suitable for lithium-ion/polymer cells are those which also meet the other standards (chemical compatibility, no aging, etc.) such as LiFePO₄, Li₄Ti₅O₁₂.

Over very extended periods of usage, it is possible that even the extremely small currents drawn for making the voltage measurements could drive the reference electrode to complete lithiation or de-lithiation where a significant change in the voltage could take place. This can be avoided by periodic passing of small currents between the reference electrode and the anode or the cathode or any other electrode to bring the state of the reference electrode to one where it is well within the flat voltage window.

With proper cell design, the choice of materials for the reference electrode can be extended to even those without a flat voltage curve. In these cases, cell geometries with effective diffusion barriers shall be selected. This second embodiment can be used alternatively or in addition with the conditions of the first one.

The theoretical basis rests with diffusion characteristics within the separator. Fick's second law describes how diffusion causes the concentration field to change with time:

$$\frac{\partial {C}_{0} ( x , t )}{\partial t} = {D}_{0} \frac{{\partial }^{2} {C}_{0} ( x , t )}{\partial {x}^{2}}$$

This equation can be solved for a discrete step change in concentration from an initial homogenous concentration (C*) to another concentration at position x=0. Often, this equation is solved under the following boundary conditions where the concentration at x=0 (C₀) is taken to equal that in the bulk (C*) initially (t=0) and zero at other times

$${C}_{0} ( x , t ) = {C}_{0}^{*} ( for t = 0 )$$

$${lim }_{x \to ∞} {C}_{0} ( x , t ) = {C}_{0}^{*}$$

$${C}_{0} ( 0 , t ) = ( for t > 0 )$$

The solution to the Fick's second law is then given by the following equation where D₀ is the diffusion coefficient of the species.

$${C}_{0} ( x , t ) = {C}_{0}^{*} erf [ \frac{x}{2 {( {D}_{0} t )}^{1 / 2}} ]$$

This equation describes that the zone near x=0 where the concentrations differs from those of the bulk (which is commonly referred to as the diffusion layer) does not have a finite thickness, but reaches bulk concentration values asymptotically (see Angew. Chem. Int. Ed. Engl. 32 (1993) 1268). However, it is common to approximate the diffusion layer thickness in terms of (D₀t)^{1/2}, which has units of length and characterize the distance that the species can diffuse in time t (See: A. J. Bard, L. R. Faulkner, “Electrochemical Methods: Fundamentals and Applications,” 2^{nd} ed., John Wiley & Sons, New York, 2000.) An often used equation to calculate the diffusion layer thickness is the following:

Diffusion layer thickness (γ)=2(Dₛt)^{1/2}

Here, the notation Dₛ is used instead of D₀ merely to indicate the more solid nature of separator in lithium polymer cells (gels, ceramics, etc.)

Table 2 gives the values for Dₛ and transference numbers for several typical electrolytes used in lithium-ion cells.

TABLE 2

| | Ds at 25° C. | |
|---|---|---|
| Electrolyte | (cm²/s) | t+ |
| EC/DMC | 3.001 * 10⁻⁸ | 0.598 |
| EC/EMC | 5.306 * 10⁻⁸ | 0.671 |
| EC/DEC | 3.834 * 10⁻⁸ | 0.441 |

FIG. 5 illustrates the distance versus time profile for EC/DMC. As seen, the very low value of Dₛ (2-3 orders of magnitude lower than for some aqueous species) means that the diffusion layer grows extremely slowly. For example, even at ca. 9 hours, the layer grows to only about 600 μm. This implies that if the reference electrode is placed a short distance from the anode and the cathode, it would not be sensitive to any fluctuations in the salt concentration in the separator region between the anode and the cathode.

A reasonable range for the diffusion distance can be arrived at by considering the range of charge/discharge rates (C-rates) associated with lithium batteries (C is the charging/discharging rate, defined as follows: 1 C means a complete charge or discharge within 1 hour. The factor 1, 2 or the like C means that complete charging/discharging is performed within a time which is 1 h divided through said factor, i.e. 2 C means half an hour and 100 C means 1/100 of an hour). For nearly all applications, the charging is done at rates no slower than 0.1 C with more common rates falling within 1 C and 10 C. The same holds true for discharge except the high discharge rates could extend up to about 30 C.

The following table summarizes the diffusion distances associated with different C-rates. The distance is calculated according to the standard diffusion distance equation: distance=2(Dt)^{1/2}. Typical organic solvents for lithium batteries have a D in the order of 1×10⁻⁸ cm²/s.

| Charge/Discharge | Charge/Discharge Time | Diffusion distance/ |
|---|---|---|
| Rate (C-Rate) | (seconds) | mm |
| 100 C | 36 | 0.02 |
| 30 C | 120 | 0.04 |
| 20 C | 180 | 0.05 |
| 10 C | 360 | 0.07 |
| 1 C | 3600 | 0.21 |
| 0.1 C | 36000 | 0.66 |
| 0.01 C | 360000 | 2.08 |

Therefore, during normal battery usage (1 C to 30 C) it is unlikely that the lithium concentration changes in the separator region beyond 1 mm from the perimeter of the anode and cathode. Taking this into account, the distance between the boundaries of the reference electrode and those of the adjacent electrode should be in this embodiment at least 0.3 mm, preferably at least 0.7 mm, more preferably at least or larger than 1 mm, even more preferably at least 1.5 mm, even more preferably at least 2.1 mm and most preferably at least 2.8 mm.

FIG. 6 shows how such a diffusion barrier can be implemented in a full cell. Here, the gap on the lateral plane (x-y direction) of the reference electrode is shown, but a similar gap is allowed in the vertical plane (x-z or y-z) as well.

Selecting a proper diffusion barrier as outlined above results in masking the reference electrode from possible voltage drifts caused by fluxes of Li⁺ ions.

Selecting a suitable cell geometry may further aid minimization of the voltage drift in that effective gaps for heat dissipation are provided:

The Fick's law governs the diffusion of heat through a medium in the same manner it does the diffusion of chemical species. Therefore, the same arguments as above could be made for the use of an effective gap for the dissipation of heat. In a battery, heat is generated at the anode and/or cathode during charge and/or discharge. The amount of heat depends on the charge and/or discharge rate. The reference electrode potential (as seen in the Nernst equation above) can be sensitive to this if it is placed very close to the anode and/or cathode. In this invention described, the reference electrode is surrounded by a separator through which the heat generated at the anode and/or cathode can dissipate. Therefore, the distance of heat transfer versus time plot would have a similar shape as that in FIG. 6 governed by the heat diffusivity within the separator. However, heat dissipation can be expected to be drastically reduced when the heat can also escape perpendicularly from the separator to the surrounding air as possible in some designs. These effects are exploited in rendering the reference electrode insensitive to any temperature fluctuations.

Selecting a proper gap for heat dissipation provides masking of the reference electrode from possible voltage drifts caused by fluxes of Li⁺ ions and/or due to temperature fluctuations.

According to the present invention, the reference electrode has manufacturing compatibility with standard lithium-ion/polymer processes (lithium batteries or accumulators in sheet form). In most cases, these processes involve preparation of a pasty mass made of the respective electrode material and a binder (in most cases an organic polymer), optionally in admixture with a plasticizer and/or with a solvent having high volatility and/or with a conductivity enhancer, e.g. a carbon material having a high surface, as carbon black or graphite. The pasty mass is brought into film form and dried or cured, to provide an electrode film. The separator can be made accordingly, except that no electrode material may be incorporated, but possibly a solid electrolyte material. Alternatively, the separator can be made of a gel-like organic polyelectrolyte.

Except the case that the electrical conducting structure extending through a wall of the casing for further electrical connection of the reference electrode is made of the material of the reference electrode, as outlined above, it will usually be a metallic foil or sheet. Further, a metallic foil or sheet may act as a current collector of the reference electrode. In these cases, it is usually covered with reference electrode material, e.g. by lamination or coating. In specifically preferred cases, the electrical conducting structure extending through a wall of the casing and the current collector are made integral, for example are one piece of metal or expanded metal.

That part thereof which extends inside the electrochemical cell is then at least partly covered with reference electrode material. In preferred embodiments, the metallic foil or sheet is made of copper (specifically preferred for lithium titanate) or aluminum (specifically preferred for LiFePO₄).

In a specific embodiment of the invention, the metallic foil or sheet is covered with a layer of the reference electrode material on both sides, preferably by coating or lamination. This is specifically advantageous if the electrode material comprises some binder, as it is usually the case. The double-sided coating allows a stronger binding to the top and bottom separator in embodiments where the reference electrode is sandwiched between two separators. In these embodiments, a reference electrode applied to only one side of the current collector would result in the danger that the uncoated side would either have a poor contact to the separator or would become separated over the time. Both scenarios would compromise the performance (e.g. would cause electrical short-cuts) and/or the physical integrity of the cell (e.g. ripping off of the separator).

The electrical conducting structure extending through a wall of the casing for further electrical connection of the reference electrode has usually the shape of a tab which extends through the package or casing of the electrochemical cell, like it is usually the case with the current collectors of the anode and the cathode.

In a preferred embodiment of the invention, the reference electrode is electrically insulated from the negative electrode and from the positive electrode via the separator material and/or via an electrically insulating coating provided on the reference electrode and/or on one of the electrodes. Such an embodiment can for example be realized by providing at least two separator layers in vicinity to each other and the only or more than one reference electrode(s) is/are placed between two of the said separator layers.

If the electrodes and the separator have layer form, they usually have their larger extensions in x-y direction, for example in a cm range, compared with their thickness (extension is z-direction) which is usually much lower. The cell geometry is freely selectable, the area of each layer of the electrode or separator in common applications being selected in most cases between around 0.25 cm² up to 100 cm² or even more (e.g. ≧1 m²), for example in cases where the cell will be used in rolled form. The thickness can be in the range of between 10 and 1000 μm and preferably between 70 and 300 μm. Although their shape is freely selectable, the cells are often flat or have been rolled up to a cylinder, so that the single electrode and separator layers can have a length and/or width in the range of 1 mm to more than one meter or even more.

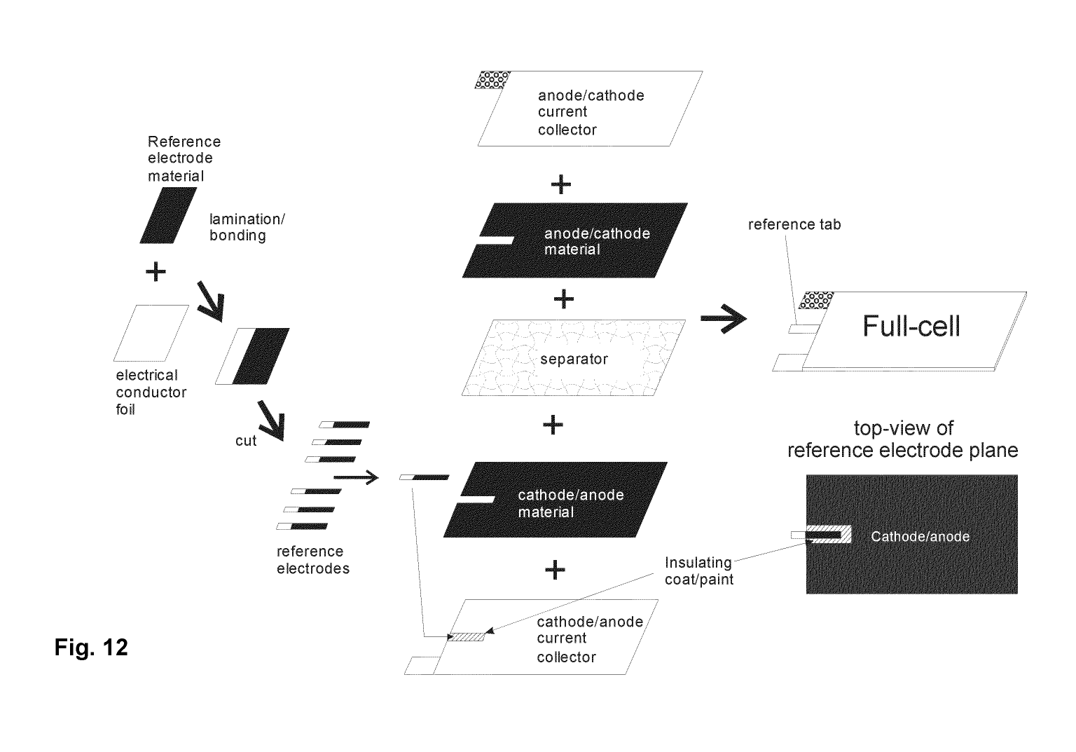

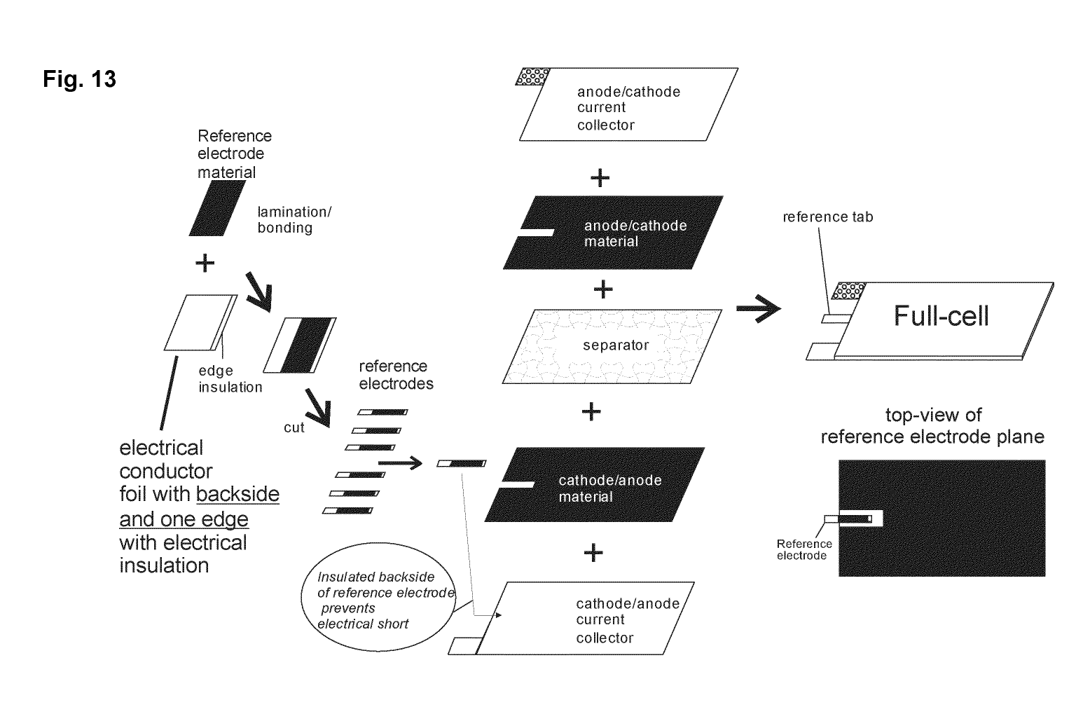

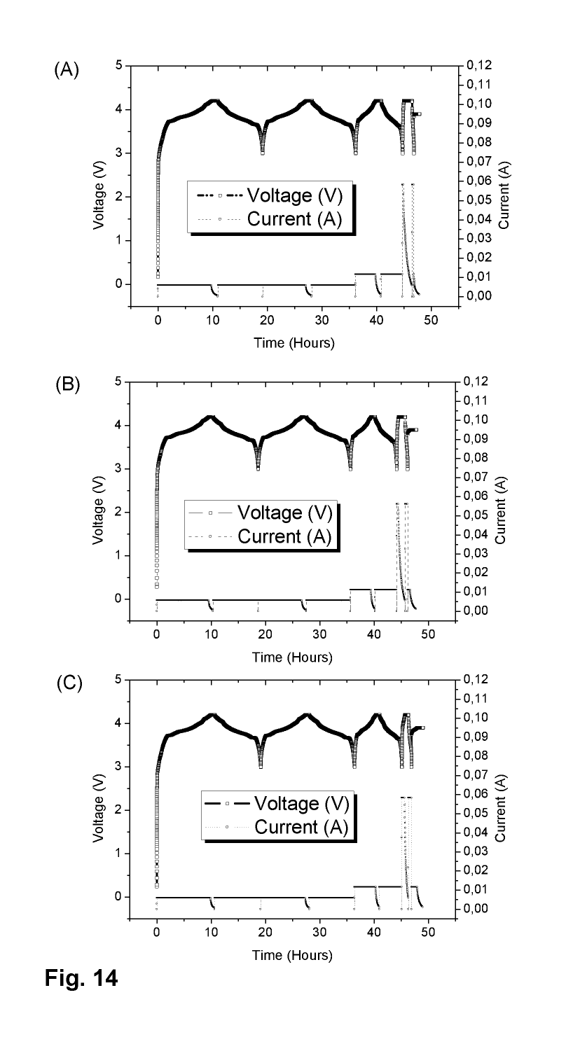

There are different possibilities of configuration of the electrochemical cell of the present invention in order to meet the requirements of the second embodiment (minimum distance between the boundaries of the reference electrode and those of cathode and anode). Some variants of them can be described as indicated below; specific designs thereof are depicted in the accompanying figures:
(a) The reference electrode is placed outside the area of the positive electrode and/or the negative electrode (the area being defined as a layer in x-y direction, i.e. the term “outside” is used when the cell is looked at from above, in z-direction), see e.g. FIGS. 10 and 11.
(b) The structure as mentioned in (a) can further be designed such that the length or the width of the separator layer is larger than that of the electrode layers and the layers are placed one on top the other such that the separator layer projects from the electrode layers on one side of the battery, characterized in that the reference electrode is attached to the separator layer along its projecting length, see FIG. 11.
(c) Alternatively, the structure as mentioned in (a) can further be designed such that at least one of the electrodes has a recess or notch cut out of the layer, and the reference electrode, seen in z-direction, is placed in the area of the said notch or recess of one of the electrodes. In these cases, it is preferred that two separator layers are present and that the reference electrode is placed between the said separator layers, see FIG. 10. Placement of the reference electrode outside the planes of the cathode and the anode avoids electrical field effects arising from the anode and/or cathode which may disturb the reference potential. Further, within the separator, the least fluctuations in Li⁺ concentration take place.
(d) The reference electrode can be placed on one of the cathode current collector and the anode current collector, separated therefrom by an insulating material, such that it is situated within the recess or notch of the adjacent electrode, see FIG. 12 or 13. The insulating material can be provided as an insulating coat or paint situated on the respective cathode or anode current collector, see FIG. 12, and/or on the side of the reference electrode or its electrical conductor foil which faces the respective current collector, see FIG. 13. The gap between the reference electrode and the adjacent electrode within the level or plane of said electrode should in these cases also be filled with insulating material. Alternatively, this gap can be filled with material from the adjacent separator, which is pressed into it during lamination and sealing of the cell.
   (e) In specific embodiments of the invention, the electrochemical cell based on lithium technology may contain two or more reference electrodes. These can be electrically connected inside or outside the cell, or they can be situated electrically separated from each other, for example in order to provide separate measurements of aging phenomena of the cathode and the anode. They may be made of the same material, e.g. from one of Li₄Ti₅O₁₂ or LiFePO₄, or of different materials, e.g. one of Li₄Ti₅O₁₂ and the other of LiFePO₄.
(f) In specific variants of embodiments according to the preceding item (e), one of the reference electrode is placed on the cathode current collector and the other or one other thereof is placed on the anode current collector.

Masking of the reference electrode, if desired, can optionally be performed by placing it outside the flux of Li-ions, e.g in the separator region slightly laterally away from the space between the anode and cathode, seen from the top or bottom along the Z-axis (in z-direction), or in the plane of an electrode or current collector, outside the anode/separator/cathode sandwich, e.g. within a recess or notch of the electrode or current collector, or being situated with the necessary distance to and along an x or y boundary thereof.

In general, the electrochemical cells based on lithium technology according to the present invention can be prepared using the same and comparable steps, relative to known electrochemical lithium cells. Preferably, the cells are prepared using the following steps:
a) Preparation of the anode, cathode, and reference electrode
b) Layering of all required materials one on top the other (i.e., laminating current collectors, anode and cathode materials, and polymeric separator together)
c) Connecting tabs to the electrodes and enclosing everything in a foil pouch
d) Filling liquid electrolyte (if necessary) and sealing the pouch under inert, water-vapor-free atmosphere.

A reference electrode in a lithium polymer battery would enable the following benefits:

Simultaneous monitoring of the voltage of the anode and cathode: State-of-the-art (SOA) lithium-ion/polymer batteries consist of a 2-electrode configuration (anode and cathode). The integration of a fully functional internal reference electrode would allow the determination of the voltage over the cathode and the anode loops independently. Furthermore, knowledge of the anode and cathode voltages enables the calculation of the full cell voltages which is the sum of the anode and cathode voltages against the reference electrode. Alternatively, by the same mathematical relationship, if the full cell voltage is measured and only one of the cathode and anode voltages is measured, then the other can be calculated.

Enhanced safety of use: Knowledge of the voltages of the anode and cathode can increase the safety of the battery by providing information on when the anode and/or the cathode reaches unsafe voltages. For example, in this manner, common problems plaguing lithium batteries such as the formation of lithium dendrites on the anode and the onset of dangerous oxidation processes at the cathode may be avoided. In a 2-electrode system, where only the voltage difference between the anode and cathode (ΔV) is known, a normal ΔV may mask the breach of the safe potential limit as shown in FIG. 1. In a system with a reference electrode, a battery management system can be used to deactivate or alter the operation of the battery whenever unsafe voltages are registered. The battery management system would have the basic properties (but not limited to) those outlined in FIG. 2. Added features and options to the management system can include the selection of the frequency of voltage measurements (e.g., continuous or periodic with varying time intervals), storage of measured data for tracking battery history, etc.

Optimal Use of Battery:

(A) Energy density: To obtain the maximum capacity out of a battery, it is often necessary to drive the voltage of the anode and/or cathode very close to the safety limits. However, in the absence of a reliable method to determine the individual voltages at the anode and cathode, some trade-offs between safety and capacity yield must be made (i.e., the battery remains with an offset voltage buffer at both charge and discharge ends). For example, the situation with a graphite anode highlights such a trade-off. During charging of graphite, the capacity stored over the voltage drop down to 0.1 V (vs. Li/Li⁺) is ˜100 mAh/g whereas more than 300 mAh/g capacity is stored between 0.1 and slightly above 0 V (H. Nozaki et al., J. Power Sources 194 (2009) 486-493). A reliable control of the voltage, as provided by a reference electrode, would enable optimum use of this capacity (i.e., without risking dendrite growth or electrolyte oxidation).

(B) Power density: At high charge and/or discharge rates, the chances of overshooting the voltage limits are increased. An inbuilt reference electrode can alleviate this problem in a manner similar to that described in (A) above.

(C) Longer battery life: Too high or too low voltages on the anode and/or cathode can shorten the battery life due to multiple reasons including deleterious film formations which cause capacity fading, lithium deposition on the anode, electrolyte degradation, electrode material dissolution, and undesirable chemical reactions involving trace impurities (e.g., reactions involving H₂O leading to HF formation). Tracking the anode and/or cathode voltage allows the battery to avoid such situations in a manner similar to that described in “Enhanced safety of use” above.

Simultaneous monitoring of the impedance on the anode and cathode loops: Inbuilt reference electrodes in laboratory scale half-cells have shown that it is possible to measure the impedance over the anode-reference and cathode-reference loops independently, thus allowing, for example, the monitoring of the relative contributions of the anode and cathode towards the overall impedance of the battery. D. P. Abraham, R. E. Reynolds, E. Sammann, A. N. Jansen, D. W. Dees, Electrochim. Acta 51 (2005) 502). In this manner, it would be possible to determine the aging properties of the anode and cathode independently. The degradation of the current collectors (e.g., due to corrosion, film formation) will also be reflected in a rise in impedance. In principle, impedance data from different frequency regimes can provide additional information such as the rate of charge transfer, double layer capacitance, conductivity and diffusion coefficients, etc., based on well known principles of electrochemical impedance spectroscopy (IES). (S-M. Park and J-K Yoo, Anal. Chem., 75 (2003) 455 A.)

Apart from monitoring the above diagnostic parameters which evolve gradually with time, impedance measurements along both the anode and cathode circuits could be helpful in diagnosing imminent battery failure (e.g., film formation from rapid electrolyte degradation, loss of SEI protection, disintegrating electrical contacts, etc.). This would be indicated by a rapid rise in either the impedance of the anode and/or cathode circuits. Such information may not be readily available from a 2-electrode system. This is because the impedance is known to change with the amount of lithium in the electrode materials, so opposing trends in the anode and cathode weaken the diagnostic value of the impedance measured in such a system. Moreover, the independent information of the evolution of the anode and cathode impedances can provide useful information for identifying which of the two is most vulnerable to aging, thus aiding in the design of better batteries. The impedance measurements can be part of a battery management system where key decisions such as when to discontinue the battery can be made (FIG. 3).

State-of-Charge (SOC) Measurement:

The SOC for lithium ion/polymer cells is defined as the available capacity with respect to a percentage of some reference capacities. Often, this reference capacity is a fully charge cell, so a 100% SOC means a fully charged cell while a 0% SOC means a fully discharged cell.

One key state-of-the-art means of measuring SOC takes into account the relationship between the cell voltage (between anode and cathode) and charge level of a cell. Indeed, this is extremely useful in the case of lead-acid batteries where there is a linear relationship between the voltage and level of charge. The same holds true for lithium ion/polymer cells when the voltage of the anode and/or cathode changes with SOC. Once such a calibration curve has been established, the SOC can be estimated from the measured voltage.

However, there is a well recognized source of error with the above way of measuring SOC which is associated with hysteresis in that the SOC estimated from the voltage is affected by the history discharge or charge history. In full cell measurements, any hysteresis of the anode and cathode are added, so the SOC derived from the voltage measurement has errors contributing from both the cathode and the anode.

An alternative way to determine the SOC is to relate it to the voltage of the cathode or the anode to the SOC. This is only possible when a reference electrode is present and the anode or cathode voltage is measureable. By measuring the SOC in this way, only the hysteresis of the anode or cathode contributes to the measurement error. In practice, the same steps as described above in deriving the SOC from the full cell voltage would be followed except the voltage is concerned (and the calibration curve) with the anode or cathode voltage

Consequently, the present invention further comprises a method for measuring the voltage of a cathode and/or of an anode of an electrochemical cell based on lithium technology, wherein the cell includes the following components:
a positive electrode containing a cathode material,
a separator made of an electrically insulating material,
a negative electrode containing an anode material, the electrodes and the separator having layer or sheet form,
a liquid and/or solid ion conductor material for transportation of lithium ions between the positive and the negative electrode,
a reference electrode in layer or sheet form which is electrically insulated from the cathode and the anode, comprising at least one non-metallic lithium compound and being in electrical contact with an electrically conducting structure in layer or sheet form,
the said components being sealed within a casing, wherein the positive electrode and the negative electrode each comprise an electrically conducting structure which, as well as the electrically conducting structure being in electrical contact with the reference electrode, extend through a wall of the casing for further electrical connection, the method including the following steps:
(a) charging and/or discharging the cell once or more times,
(b) measuring the voltage between the cathode and the reference electrode and/or between the anode and the reference electrode once or more times, and subsequently
(c) settling the rest potential to a desired value between the charge and discharge value.

In this method, the voltage of a cathode and of an anode of the said electrochemical cell based on lithium technology can be measured simultaneously by measuring the voltage between the cathode and the reference electrode and between the anode and the reference electrode simultaneously.

In a further embodiment of this invention, in the said method, the anode and/or cathode voltage is measured by measuring the voltage between the cathode and the reference electrode or the voltage between the anode and the reference electrode, and a state-of-charge (SOC) of the cell is derived therefrom, using a pre-determined or in situ calibration curve relating the SOC of the cell to the anode or cathode voltage.

In all these embodiments, the voltage between the cathode and the anode can be measured in addition, in order to prove whether the equation

ΔV_{C-A}=ΔV_{C-Ref}+ΔV_{A-Ref}

wherein C is the cathode, A is the anode, and Ref is the reference electrode, is fulfilled.

Further, in all these embodiments, the charging and/or the discharging of the cells is made once or more than once or twice and the charging and the discharging is either made at constant C rates or at or at varying rates.

In a specific embodiment, more than one measurement of voltage is performed and between two of such measurements, a small current is passed between the reference electrode and the cathode or the anode, to bring the state of the reference electrode to one where it is well within a flat voltage window.

Further, the present invention comprises a method for measuring impedance of a cathode and of an anode of an electrochemical cell based on lithium technology independently, characterized in that the cell includes the following components:
a positive electrode containing a cathode material,
a separator made of an electrically insulating material,
a negative electrode containing an anode material, the electrodes and the separator having layer or sheet form,
a liquid and/or solid ion conductor material for transportation of lithium ions between the positive and the negative electrode,
a reference electrode in layer or sheet form which is electrically insulated from the cathode and the anode, comprising at least one non-metallic lithium compound and being in electrical contact with an electrically conducting structure in layer or sheet form,
the said components being sealed within a casing, wherein the positive electrode and the negative electrode each comprise an electrically conducting structure which, as well as the electrically conducting structure being in electrical contact with the reference electrode, extend through a wall of the casing for further electrical connection, the method including the following steps:
(a) applying a constant voltage between the cathode and the anode
(b) measuring the impedance across least one of the Z_{C-Ref} and Z_{A-Ref} loops, wherein C is the cathode, A is the anode, and Ref is the reference electrode.

In this method, it is possible that the result from measuring the impedance is used for an assessment of aging of at least one of the electrodes, including the additional steps:
(c) assessing whether the said impedances are within an acceptable range
   if no, terminating the cell;
   if yes, re-measuring the impedance and repeating the loop, and either
(d) logging the impedance rise of the anode and cathode to estimate the aging of each and thereby estimating the life-time of the cell,and/or
(e) estimating the power capability losses at the anode and/or cathode by associated impedances.

The present invention further provides a method for managing an electrochemical cell based on lithium technology, comprising the following steps:
providing an electrochemical cell based on lithium technology according to the present invention,
measuring the voltage between
   (i) the anode and the reference electrode (ΔV_{anode}) and/or
   (ii) the cathode and the reference electrode (ΔV_{cathode}),
checking whether the said voltages are within an acceptable range, and
either, if yes, measuring the said voltages again, if required,
or, if no, checking whether the magnitude of voltage breach is beyond a critical point, and
   if yes, terminating the operation of the cell, or
   if no, varying the charging rate and/or discharging rate and subsequently measuring the said voltages again, if required.

In addition, the present invention provides a method for managing the optimal use of a battery, comprising the following steps:
providing an electrochemical cell based on lithium technology according to the present invention,
measuring the voltage between
   (i) the anode and the reference electrode (ΔVanode) and
   (ii) the cathode and the reference electrode (ΔVcathode),
determining the individual voltages at the anode and the cathode, and
settling the voltage difference to the optimum available for the said battery.

Finally, the present invention provides a method for maximizing the life of a battery, comprising the following steps:
providing an electrochemical cell based on lithium technology according to the present invention,
measuring the voltage between
   (i) the anode and the reference electrode (ΔVanode) and/or
   (ii) the cathode and the reference electrode (ΔVcathode),
determining the individual voltages at the anode and the cathode, and
assessing whether the said voltages are too high and/or too low, and
if required, correcting the voltage applied to the cathode and/or the anode to acceptable values.

The present invention includes batteries and accumulators of any type and for any use, e.g. batteries for consumer electronics (MP3 players, mobile phones), batteries for the automotive sector (e.g., batteries for electric and hybrid vehicles), large batteries for storing energy from renewable sources (e.g., solar and wind energy), and the like.

The following examples illustrate various embodiments of the electrochemical cell of the present invention as well as of measurement methods using same.

### EXAMPLE 1

### Preparation of Electrodes

Positive electrode: A positive electrode containing the cathode material lithium cobalt oxide (LiCoO₂) was prepared by a casting process. The casting slurry consisted of a homogeneous mixture in acetone of LiCoO₂, graphite, carbon black, and PVDF as binder (Kynar LBG2) in the ratio 90%, 2.5%, 2.5%, and 5%, respectively. The slurry casting was done with a doctor-blade onto a plastic foil resting on a flat glass substrate. Following the evaporation of solvent the specific capacity of the cathode was determined to be 3.15 mAh/cm² and a thickness of 208 μm. The electrode material laminated onto an aluminum current collector with a thickness of 120 μm.

Negative electrode: A negative electrode containing the anode material graphite was prepared by a casting process. The casting slurry consisted of a homogeneous mixture in acetone of graphite, carbon black, and PVDF as binder (Kynar LBG2) in the ratio 85%, 5%, 10%, respectively. The slurry casting was done with a doctor-blade onto a plastic foil resting on a flat glass substrate. Following the evaporation of solvent the specific capacity of the anode was determined to be 3.47 mAh/cm² and a thickness of 135 μm. The electrode material laminated onto a copper current collector with a thickness of 120 μm.

Reference electrode: A reference electrode containing the reference electrode material lithium-titanate-oxide (Li₄Ti₅O₁₂) was prepared by a casting process. The casting slurry consisted of a homogeneous mixture in acetone of Li₄Ti₅O₁₂, carbon black, graphite, and PVDF as binder (Kynar LBG2) in the ratio 82%, 4%, 2% and 12%, respectively. The slurry casting was done with a doctor-blade onto a plastic foil resting on a flat glass substrate. Following the evaporation of solvent the specific capacity of the anode was determined to be 2.51 mAh/cm² and a thickness of 175 μm. The electrode material was laminated onto a copper current collector with a thickness of 120 μm.

### EXAMPLE 2

### Characterization of Electrode Materials

Linear sweep voltammetry (LSV) or cyclic voltammetry (CV) was performed on the three types of electrodes prepared according to Example 1. All experiments were carried out in electrochemical cells where lithium metal foil acted as a reference and counter electrode. The electrolyte used was a battery grade mixture of 1:1 ethylene carbonate (EC) and dimethylcarbonate (DEC) containing1M LiPF₆. The electrode area of the working electrodes (i.e., cut out circles of electrode foils in Example 1) was 1.3 cm². All experiments were carried out under an argon atmosphere. Slow scan rates were used in order to better resolve voltammetric peaks. In particular, 10 μV/s was used for both graphite and Li₄Ti₅O₁₂ and 100 μV/s for LiCoO₂ to obtain the voltammograms of the electrodes (FIGS. 7-9).

With LiCoO₂ 3 cycles were carried out in order verify the evolution of the voltammetric peaks with multiple scans (FIG. 7). In the case of LiCoO₂, there is a noticeable difference between the first and the second scans: the anodic peak shifts to a slightly negative voltage and a lower peak current whereas the cathodic current is marked by a resolution of a new peak (i.e., between 3.8 V and 3.7 V) on the second scan. The difference between the second and third scans is small, indicating that the formation of the active surface of LiCoO₂ is essentially complete by the third scan. This type of evolution of the CVs scans is in full agreement with literature (Ref: Dana A. Totir, Boris D. Cahan and Daniel A. Scherson, Electrochimica Acta 45, 161-166 (1999)) and attests to the with high quality LiCoO₂.electrodes.

In the case of graphite, the peak evolution is much more drastic due to the formation of the classic solid-electrolyte-interface (SEI) described in literature (Ref: H. Wang and M. Yoshio, Journal of Power Sources 93, 123-129 (2001)). The uniformity of scans following the second scan indicates the SEI formation is complete. The FIG. 8 shows the CV upon the third cycle. Here, too, the CV is in agreement with literature.

The LSV of Li₄Ti₅O₁₂ shows a sharp peak with a steep ΔA/ΔV gradient (FIG. 9). At the scan rate of 10 μV/s of the sweep used in this experiment, the ΔA/ΔV is ca 20 mV/mA. This very small gradient (which will be even smaller at lower sweep rates (A. J. Bard, L. R. Faulkner, “Electrochemical Methods: Fundamentals and Applications,” 2^{nd} ed., John Wiley & Sons, New York, 2000) and the absence of multiple and broad peaks as seen with LiCoO₂ and graphite supports the function of a classic non-polarizable electrode property (i.e., very little shift in voltage with increasing current) of a reference electrode, the method of use of Li₄Ti₅O₁₂ in this invention.

In summary, all three electrode materials (anode, cathode, and the reference electrode) produced in Example 1 show the type of electrochemical performance expected of high quality electrodes and prove their suitability for the construction of full lithium polymer cells as described in the following Examples 3-5

### EXAMPLE 3

### Full Cell Design 1 and the Construction Thereof

Full cells were constructed using the electrode material prepared as described in Example 1 and a separator containing Li_{1.3}Al_{0.3}Ti_{1.7}(PO₄)₃ and PVDF in the ratio of 75% and 25%, respectively. The thickness of the separator was 55 μm. FIG. 10 illustrates the cell construction scheme for one embodiment of the invention.

The cathode material was laminated onto aluminum current collector of 120 μm thickness. The anode was laminated onto copper current collector of 120 μm thickness. Both the cathode and the anode had outer dimensions of 58×33 mm with an indent of 8×5 mm cut into the electrodes from the center of one side. The separator was slightly oversized compared to the anode and cathode. The reference electrode material was laminated on to a copper current collector of 120 μm thickness. The reference electrodes for the cell were obtained by cutting strips where the cut over the active electrode material (Li₄Ti₅O₁₂) was slightly undersized compared to the indent of the anode and cathode. A reference electrode strip was inserted between the two separators in a way that the reference electrode was directly aligned in the indent of the anode and cathode. The full system was laminated under heat and pressure. The resistance measurements showed that there was no electrical short-cut between the reference electrode and the other two electrodes. All laminated parts, including the reference electrode, were held together strongly as verified by the robustness of the components towards gentle pulling. The cell was housed in a heat-seal foil pouch, the standard electrolyte mixture of 1:1 ethylene carbonate (EC) and dimethylcarbonate (DEC) containing1M LiPF₆ was filled, and the complete system sealed in a glove box under argon.

### EXAMPLE 4

### Full Cell Design 2 and the Construction Thereof

Another embodiment of the invention is illustrated in FIG. 11. The electrode material used were the same described in Example 1. The design differs from that described in Example 2 in the following: i. The reference electrode is aligned along one of the long edges of the full cell, ii. the anode and cathode areas are 58×33 mm each and contain no indent. The full system was laminated under heat and pressure. The resistance measurements showed that there was no electrical short-cut between the reference electrode and the other two electrodes. All laminated parts, including the reference electrode, were held together strongly as verified by the robustness of the components towards gentle pulling. The cell was housed in a heat-seal foil pouch, the standard electrolyte mixture of 1:1 ethylene carbonate (EC) and dimethylcarbonate (DEC) containing1M LiPF₆ was filled, and the complete system sealed in a glove box under argon.

### EXAMPLE 5

### Other Full Cell Designs

Two other embodiments differing from those in Example 2 and 3 in that only one separator is used. Direct electrical contact between the reference electrode and the anode as well as the cathode are avoided by having an electrical insulation coating on the anode/cathode (FIG. 12) or on the reference electrode (FIG. 13). Alternatively, the electrical insulation coating could be made on both the reference electrode and anode/cathode for even better protection.

### EXAMPLE 6

### Establishing that the Physical Presence of a Reference Electrode does not Perturb the Normal Charge-Discharge Behavior of a Cell

Two full-cells of the type described in Examples 3 and 4 were tested in the standard 2-electrode charge-discharge mode (i.e., without any use of the reference). A control experiment was conducted with a full cell without a reference electrode but otherwise identical in geometry and composition to the full-cell described in Example 4. The experiment would reveal whether the physical presence of the reference electrode would impact the performance of a battery. FIG. 14 shows representative results from freshly prepared full-cells under the common constant current-constant voltage protocol (CC-CV) with a) two full cycles at 0.1 C CC-phase, b) 1 full cycle with 0.2 C CC-phase, c) 1 full cycle with 1 C CC-phase. The final resting potential was set to 3.8 V under 0.2 C. The voltage window was between 3.0 and 4.2 V. A TOSCAT 5200 battery cycler (Toyo Systems Co, Ltd, Japan). (CC means constant current; CV means constant voltage).

It is apparent from FIG. 14 that with respect to both the voltage vs. time plot and the current vs. time plot the profiles of the two full cells with reference electrodes (FIGS. 14b and c) show similar behavior to the standard full cell (FIG. 14a). Therefore, it can be concluded that the physical presences of the reference electrode of the invention does not impact the normal charge-discharge behavior of a full cell.

### EXAMPLE 7

### Simultaneous Measurement of Voltage Between a) Anode-Cathode, b) Cathode-Reference, and c) Anode-Reference upon Continuous Charge-Discharge Cycles

A three-electrode cell with a reference electrode as described in the invention was cycled 10 times under constant charge and discharge at 1 C between 3.0V and 4.2V followed by settling rest potential of 4.0 V. In addition to the normal measurement of the voltage between the cathode and the anode (ΔV_{C-A}), the same values were measured simultaneously between the anode and the reference electrode (ΔV_{A-Ref}) and the cathode and the reference electrode (ΔV_{C-Ref}). A TOSCAT 5200 battery cycler was used for the cycling while a voltmeter was used to measure the voltages between the reference electrode and the anode and cathode. The full set of voltage measurements are shown in FIG. 15. All voltage curves show identical periodicity with ΔV_{C-A}=ΔV_{C-Ref}+ΔV_{A-Ref}. This confirm that it is possible to measure ΔV_{A-Ref} and ΔV_{C-Ref} simultaneously. Here the anode and cathode voltages are given with respect to the lithium titanate (LTO) reference electrode. Based on the LTO electrochemical potential versus lithium, it is possible to calculate the voltage windows for the anode and cathode with respect to Li/Li⁺ or any other reference voltage if necessary.

### EXAMPLE 8

### Measurement of the Impedance of the Anode and Cathode Loop in a 3-Electrode Battery Using the Reference Electrode

Impedance measurements were made using a Zahner IM6 (Zahner-elektrik GmbH, Kronach, Germany). In order to verify the behavior and relationship between the impedance loops across the anode and cathode (Z_{C-A}), the anode and reference (Z_{A-Ref}), and the cathode and reference (Z_{C-Ref}), the temperature was varied between −10° C. and 30° C. while the voltage was held constant at 4.0V. The impedance is known to be directly related to the temperature, thus providing a very convenient method to probe the impedance. FIG. 16 shows the impedance measurements across Z_{C-A} and Z_{A-Ref} loops in the form of Nyquist plots. The impedance shows a clear increase with decreasing temperature as evident in the increasing width of the semicircles. In terms of absolute values, the Z_{C-A}<Z_{A-Ref} due to the much larger surface area of the anode and cathode compared to the reference electrode, but qualitatively the impedance behavior remains very similar. FIG. 17 shows the Arhenius plot of Z_{C-A}, Z_{A-Ref}, Z_{C-Ref} versus 1/temperature for the impedance measured at 100 mHz. Here, the data suggest that Z_{A-Ref} and Z_{C-Ref} are nearly equal over the temperature range. This is to be expected considering that the decreasing temperatures are most likely to affect the impedance over the separator because of the well-known decrease in conductivity of the electrolyte within the separator with decreasing temperature. This experiment, therefore, illustrates the feasibility of measuring and following Z_{C-A}, Z_{A-Ref}, Z_{C-Re} and thus enabling the useful diagnostics of battery performance described in 1.4.

### EXAMPLE 9

### Simultaneous Measurement of Voltage Between a) Anode-Cathode, b) Cathode-Reference, and c) Anode-Reference in 3-Electrode Cell Upon Continuous Charge-Discharge Cycles at Varying Rates

A battery with a reference electrode was cycled under similar conditions as described in Example 7 except the charge-discharge profile followed the charging at a constant 0.2 C and the discharging at 1 C, 2 C, 4 C, and 6 C. Four discharges were made at each discharge rate and the full cell voltage window was set to 3.0-4.2V. FIG. 18a shows the simultaneous measurements of the voltage between a) anode-cathode, b) cathode-reference, and c) anode-reference. FIG. 18b shows the current versus time plot corresponding to the voltage above voltage curve. In this particular case, the results illustrate the important role of a reference electrode in determining the contributions of the anode and cathode to the overall cell voltage. For example, during charging the anode reaches its voltage plateau rapidly whereas the cathode rises slowly along with the rising voltage of the full cell. In a separate experiment, the discharge rate was increased drastically to determine the onset of a voltage breach due to the high power applications as described in 1.3.2. FIG. 19 shows the voltage profiles for 0.2 C charge and 8 C, 16 C, and 32 C discharge rates with three charge-discharge cycles at different C rates. The general behavior seen in FIG. 18 is continued up to 16 C. However, a significant overshoot of voltage takes place at 32 C. In this case, the discharge is so rapid that by the time the first data point for the discharge is obtained, the voltage had exceeded the 3.0V discharge limit. This also causes the voltage of the anode and cathode to exceed (compared to lower C rates) the limits by approximately 300 mV on the cathode side and 150 mV on the anode side.

### EXAMPLE 10

### Simultaneous Measurement of Voltage Between a) Anode-Cathode, b) Cathode-Reference, and c) Anode-Reference Using a Lithium Iron Phosphate (LFP) Reference Electrode

A further example of the simultaneous measurement of the above three voltages (between cathode and anode (ΔV_{C-A}), cathode and reference (ΔV_{C-R}) and reference and anode (ΔV_{R-A})) is presented for the use of lithium iron phosphate (LiFePO₄or LFP) as the reference electrode. The preparation of the cell was made as in the above case of Example 7 with the main difference being the reference electrode (LFP here). The LFP reference electrode material was prepared similar to the LTO electrode in Example 1 with the capacity of LFP being 0.7 mAh/cm².

The cell was tested with a charge-discharge cycle profile consisting of a constant-current (CC) and constant voltage (CV) charging and CC discharge. The exact sequence was as follows: (1) Discharge to 3.0 V at 0.5 C, (2) 10 cycles with each cycle having i) charge to 4.2 V at 1 C followed by a CV phase (cut-off set to current matching current of 1/10 C) ii) 1 C discharge to 3.0 V and iii) rest at open-circuit potential for 1 hour, (3) 1 cycle with i) charge to 4.2 V at 0.5 C followed by a CV phase (cut-off set to a current corresponding to 1/10 C) ii) 0.5 C discharge to 3.0 V and iii) rest at open-circuit potential for 1 hour, and (4) bring to rest at 3.7 V. FIG. 20 shows the voltage profile between the anode and the cathode (FIG. 20a) and the voltages measured simultaneously between the anode and cathode versus the reference electrode (FIG. 20b). The characteristics of a single charge-discharge cycle are seeing more clearly in the zoomed view (FIG. 20c).

All voltage curves show identical periodicity with ΔV_{C-A}=ΔV_{C-R}+ΔV_{R-A}, which confirms the possibility to measure all three voltages simultaneously using a reference electrode consisting of LFP. In this example, the voltage profiles at the anode and cathode distinguish the different characteristics (i.e., significantly greater voltage shifts at the cathode compared to the anode during charging, a greater voltage swing at the anode compared to the cathode during open circuit resting). Such information cannot be obtained with the state-of-the-art two electrode cells and is made possible here only with the aid of the reference electrode which contains LFP in this example.

### EXAMPLE 11

### Simultaneous Measurement of Voltage Between a) Anode-Cathode, b) Cathode-Reference, and c) Anode-Reference During Pulse Discharge

In the above examples of full cell tests, the charge and discharge profiles were all continuous in character (i.e., constant charging and discharging currents). Here the testing is extended to rapid discharge pulse profiles representative of typical high power characterization methods of batteries. In particular, the test is designed to ascertain the suitability of the invention to monitor the rapid voltage pulses at the anode and cathode, with the aforementioned advantages such capability offers. A cell similar to that used in Example 7 was used where the reference electrode was an LTO reference electrode.

FIG. 21 shows a series of charge-discharge cycles between 3.0 V and 4.2 V. FIGS. 21(a) and (b) show the voltage between the anode and cathode (ΔV_{C-A}) and FIGS. 21(c) and (d) show the voltages at the anode (ΔV_{R-A}) and cathode (ΔV_{C-R}) as measured against the reference electrode. All charging events were performed at 0.2 C CC-CV. The discharges were done over the range of 1-30 C as shown in FIG. 21 where i) is 1 C, ii) 2 C, iii) 5 C, iV) 10 C, v) 20 C and vi) 30 C. Here, each pulse was 18 seconds long and was followed by a 60 second open-circuit rest period before the next pulse. A 30 minute rest at open-circuit potential was allowed between discharging and charging. The results illustrate that, as expected, the time taken to complete a discharge process is inversely related to the C-rate. More importantly, here too all voltage curves show identical periodicity with ΔV_{C-A}=ΔV_{C-R}+ΔV_{R-A}, which confirms the possibility to measure ΔV_{R-A} and ΔV_{C-R} simultaneously using a reference electrode under pulse discharge conditions. Furthermore, the dynamic voltage profiles observed throughout the pulse discharges enables the tracking of the voltages at the anode and cathode in fine and exact detail even during a single 18 second pulse.

### EXAMPLE 12

### Simultaneous Measurement of Voltage Between a) Anode-Cathode, b) Cathode-Reference, and c) Anode-Reference During Pulse Charge

Here the same system as used in Example 11 was used to determine the anode and cathode behavior during pulse charge. As shown in FIG. 22, pulse charging was done at i) 1 C, ii) 2 C, iii) 3 C, and iV) 5 C with each pulse being 18 seconds long followed by a 60 second open-circuit rest period before the next pulse. The discharging was always done at 1 C in constant current (CC) and a 30 minute rest at open-circuit potential was allowed before charging again. Here, too, the results illustrate that the time taken to complete a charge process is inversely related to the C-rate. More importantly, all voltage curves show identical periodicity with ΔV_{C-A}=ΔV_{C-R}+ΔV_{R-A}, which confirms the possibility to measure ΔV_{R-A} and ΔV_{C-R} simultaneously using a reference electrode under pulse charge conditions. The voltage profiles remains dynamic throughout the pulse charges thus enabling the tracking of the voltages at the anode and cathode in exact detail even during a single pulse.

1. Electrochemical cell based on lithium technology, comprising the following components
a positive electrode containing a cathode material,
a separator made of an electrically insulating material,
a negative electrode containing an anode material, the electrodes and the separator having sheet form,
a liquid and/or solid ion conductor material for transportation of lithium ions between the positive and the negative electrode,
the said components being sealed within a casing, wherein the positive electrode and the negative electrode each comprise an electrically conducting structure extending through a wall of the casing for further electrical connection, characterized in that it further comprises:
a reference electrode within the said casing which is electrically insulated from the positive and the negative electrodes, the reference electrode having layer form comprising at least one non-metallic lithium compound within the said casing, and an electrically conducting structure in layer form being in electrical contact with the said reference electrode, the electrically conducting structure extending through a wall of the casing for further electrical connection.

2. Electrochemical cell based on lithium technology according to claim 1, further comprising a reference electrode collector, wherein the reference electrode is in electrical contact with the reference electrode collector.

3. Electrochemical cell based on lithium technology according to any of claim 1 or 2, wherein the distance between the boundaries of the reference electrode and those of the adjacent electrode is at least 0.3 mm, preferably at least 0.7 mm, more preferably at least 1.6 mm and most preferably 2.1 mm.

4. Electrochemical cell based on lithium technology according to any of the preceding claims, wherein the reference electrode is electrically insulated from the negative electrode and from the positive electrode via the separator material and/or via an electrically insulating coating provided on the reference electrode and/or on one or both of the electrodes.

5. Electrochemical cell based on lithium technology according to any of the preceding claims, wherein the electrodes and the separator are arranged one atop the other in z-direction, and each covering an area in an x-y direction and if the battery is seen from above (in z-direction), the reference electrode is placed outside the area which is covered by the positive electrode and/or of the negative electrode.

6. Electrochemical cell based on lithium technology according to any of the preceding claims, wherein the electrodes and the separator are arranged one atop the other in z-direction, and each covering an area in an x-y direction, wherein the length or the width of the separator layer is larger than that of the electrode layers and the layers are placed one on top the other such that the separator layer projects from the electrode layers on one side of the battery, characterized in that the reference electrode is attached to the separator layer along its projecting length.

7. Electrochemical cell based on lithium technology according to any of the preceding claims, wherein the electrodes and the separator are arranged one atop the other in z-direction, and each covering an area in an x-y direction, characterized in that at least one of the electrodes has a recess or notch cut out of the layer, and the reference electrode, seen in z-direction, is placed in the area of the said notch or recess of one of the electrodes.

8. Electrochemical cell based on lithium technology according to claim 2 in combination with claim 7, wherein the reference electrode is placed on one of the cathode current collector and the anode current collector, separated therefrom by an insulating material, such that it is situated within the recess or notch of the adjacent electrode.

9. Electrochemical cell based on lithium technology according to any of the preceding claims, wherein the non-metallic lithium compound is selected under Li₄Ti₅O₁₂, LiFePO₄, Li(Ni_{0.5}Mn_{1.5})O₄. LiCoO₂, LiMn₂O₄, LiNiO₂, LiNi_{0.8}Co_{0.15}Al_{0.05}O₂(NCA), LiCo_{1/3}Ni_{1/3}Mn_{1/3}O₂ (NMC), Li₂FePO₄F, Li(LiₐNiₓMn_{y}Co_{z})O₂, Graphite (LiC₆), Hard Carbon (LiC₆), Si(Li_{4.4}Si), and Ge (Li_{4.4}Ge).

10. Electrochemical cell based on lithium technology according to claim 2 or any claim depending on claim 2, characterized in that the current collector of the reference electrode and the electrically conducting structure in layer form being in electrical contact with the said reference electrode are are integrally connected.

11. Electrochemical cell based on lithium technology according to claim 2 or any claim depending on claim 2, wherein the reference electrode collector is covered with reference electrode material on both sides.

12. Electrochemical cell based on lithium technology according to any of the preceding claims, characterized in that it contains two or more reference electrodes.

13. Method for the production of an electrochemical cell based on lithium technology as claimed in any of the preceding claims, comprising the following steps:
providing a positive electrode connected to an electrically conducting structure,
providing a negative electrode connected to an electrically conducting structure,
providing a reference electrode, comprising at least one non-metallic lithium compound and connecting same to an electrically conducting structure,
providing a separator made of an electrically insulating material,
arranging the electrodes and the separator under formation of an electrochemical cell, wherein the reference electrode is electrically insulated from the positive and the negative electrodes, and
tightly encapsulating the components of the electrochemical cell within a casing such that an electrically conducting structure of each of the electrodes extends through a wall of the casing for further electrical connection.

14. A method for measuring the voltage of a cathode and/or of an anode of an electrochemical cell based on lithium technology, wherein the cell includes the following components:
a positive electrode containing a cathode material,
a separator made of an electrically insulating material,
a negative electrode containing an anode material, the electrodes and the separator having layer or sheet form,
a liquid and/or solid ion conductor material for transportation of lithium ions between the positive and the negative electrode,
a reference electrode in layer or sheet form which is electrically insulated from the cathode and the anode, comprising at least one non-metallic lithium compound and being in electrical contact with an electrically conducting structure in layer or sheet form,
the said components being sealed within a casing, wherein the positive electrode and the negative electrode each comprise an electrically conducting structure which, as well as the electrically conducting structure being in electrical contact with the reference electrode, extend through a wall of the casing for further electrical connection, the method including the following steps:
(a) charging and/or discharging the cell once or more times,
(b) measuring the voltage between the cathode and the reference electrode and/or between the anode and the reference electrode once or more times, and subsequently
(c) settling the rest potential to a desired value between the charge and discharge value.

15. Method according to claim 14, wherein the anode and/or cathode voltage is measured by measuring the voltage between the cathode and the reference electrode or the voltage between the anode and the reference electrode, and a state-of-charge (SOC) of the cell is derived therefrom, using a pre-determined calibration curve relating the SOC of the cell to the anode or cathode voltage.

16. Method according to claim 14, including the step of preparing a calibration curve relating the state-of-charge (SOC) of the cell to the anode or cathode voltage and subsequently measuring the anode and/or cathode voltage by measuring the voltage between the cathode and the reference electrode or the voltage between the anode and the reference electrode, and deriving therefrom a SOC of the cell.

17. Method according to any of claims 14 to 16, wherein more than one measurement of voltage is performed and between two of such measurements, a small current is passed between the reference electrode and the cathode or the anode, to bring the state of the reference electrode to one where it is within a flat voltage window.

18. A method for measuring impedance of a cathode and of an anode of an electrochemical cell based on lithium technology independently, characterized in that the cell includes the following components:
a positive electrode containing a cathode material,
a separator made of an electrically insulating material,
a negative electrode containing an anode material, the electrodes and the separator having layer or sheet form,
a liquid and/or solid ion conductor material for transportation of lithium ions between the positive and the negative electrode,
a reference electrode in layer or sheet form which is electrically insulated from the cathode and the anode, comprising at least one non-metallic lithium compound and and being in electrical contact with an electrically conducting structure in layer or sheet form,
the said components being sealed within a casing, wherein the positive electrode and the negative electrode each comprise an electrically conducting structure which, as well as the electrically conducting structure being in electrical contact with the reference electrode, extend through a wall of the casing for further electrical connection, the method including the following steps:
(a) applying a constant voltage between the cathode and the anode
(b) measuring the impedance across at least one of the Z_{C-Ref} and Z_{A-Ref} loops, wherein C is the cathode, A is the anode, and Ref is the reference electrode.

19. Method according to claim 18, wherein the result from measuring the impedance is used for an assessment of aging of at least one of the electrodes, including the additional steps:
(c) assessing whether the said impedances are within an acceptable range
if no, terminating the cell;
if yes, re-measuring the impedance and repeating the loop, and either
(d) logging the impedance rise of the anode and cathode to estimate the aging of each and thereby estimate the life-time of the cell,and/or
(e) estimating the power capability losses at the anode and/or cathode by associated impedances.

20. A method for driving an electrochemical cell based on lithium technology, comprising the following steps:
providing an electrochemical cell based on lithium technology according to any of claims 1 to 12,
measuring the voltage between
(i) the anode and the reference electrode (ΔV_{anode}) and/or
(ii) the cathode and the reference electrode (ΔV_{cathode}),
checking whether the said voltages are within an acceptable range, and
either, if yes, measuring the said voltages again, if required,
or, if no, checking whether the magnitude of voltage breach is beyond a critical point, and
if yes, terminating the operation of the cell, or
if no, varying the charging rate and/or discharging rate and subsequently measuring the said voltages again, if required.

21. A method for running a battery at its optimum conditions, comprising the following steps:
providing an electrochemical cell based on lithium technology according to any of claims 1 to 12,
measuring the voltage between
(i) the anode and the reference electrode (ΔVanode) and
(ii) the cathode and the reference electrode (ΔVcathode),
determining the individual voltages at the anode and the cathode, and
settling the voltage difference to the optimum available for the said battery, in order to ensure that the anode and cathode voltage limits are not exceeded.

22. A method for maximizing the life of a battery, comprising the following steps:
providing an electrochemical cell based on lithium technology according to any of claims 1 to 12,
measuring the voltage between
(i) the anode and the reference electrode (ΔVanode) and/or
(ii) the cathode and the reference electrode (ΔVcathode),
determining the individual voltages at the anode and the cathode, and
assessing whether the said voltages are too high and/or too low, and
if required, correcting the voltage applied to the cathode and/or the anode to acceptable values.
